(19) United States
(12) Patent Application Publication
(10) Pub. No.: US 2004/0011290 A1
(43) Pub. Date: Jan. 22, 2004

(54) Apparatus and process for forming deposited film

(76) Inventors: Takaharu Kondo, Kyoto (JP); Shotaro Okabe, Nara (JP); Akira Sakai, Kyoto (JP); Tadashi Sawayama, Kyoto (JP); Ryo Hayashi, Nara (JP); Hiroyki Ozaki, Kyoto (JP); Tetsuya Kimura, Kyoto (JP); Takeshi Shishido, Nara (JP)

Correspondence Address: FITZPATRICK CELLA HARPER & SCINTO, 30 ROCKEFELLER PLAZA, NEW YORK, NY, 10112, US

(21) Appl. No.: 10/457,513

(22) Filed: Jun. 10, 2003

(30) Foreign Application Priority Data
Jun. 10, 2002 (JP) 2002-168625

(51) Int. Cl. C23C 16/24

(52) U.S. Cl. 118/723 E; 427/569; 427/578

(57) ABSTRACT

A deposited film-forming apparatus by means of high frequency plasma CVD and having a power application electrode arranged in a film-forming vacuum vessel, a high frequency power source connected to said power application electrode, a direct current power source which is connected to said power application electrode and is connected with said high frequency power source in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said power application electrode and said direct current power source such that said arc discharge preventive means is connected with said direct current power source in series connection and is connected with said high frequency power source in parallel connection.

### BACKGROUND OF THE INVENTION

1. Field of the Invention

The present invention relates to an apparatus for forming a deposited film by means of high frequency plasma CVD and a process for forming a deposited film by means of high frequency plasma CVD.

2. Related Background Art

It is generally recognized that as the deposited film-forming process, a high frequency plasma CVD process is effective for quantitatively producing a deposited film in a viewpoint that deposited films can be readily formed to have large area at relatively low temperature as well as the process throughput is improved.

By having an attention on a silicon series thin film as an example of the deposited film, when consideration is made of an example of the process for producing a solar cell in which said silicon series thin film is used, although said solar cell has advantages such that the energy source is limitless and the power generation process is clean without causing pollution, it is necessitated that the price per a unit electric energy generated is decreased in order to advance the spread thereof. For this purpose, it is an important subject to establish a technique which makes it possible that the film deposition rate in the film formation by means of high frequency plasma CVD is more improved, the photoelectric conversion efficiency is more improved, and the uniformity over a large area is more improved.

Under such circumstance, various proposals have been made of the technique relating to high speed film deposition.

For instance, for the high frequency plasma CVD process in which the film deposition rate is improved, Japanese Laid-open Patent Publication No. 7(1995)-105354 discloses that when the frequency of the high frequency is made to be f(MHz) and the distance between the substrate and the electrode is made to be d(cm), focusing on the relationship between the distance d between the substrate and the electrode and the frequency f of high frequency where f is in a range of 25 to 150 MHz, the high frequency plasma CVD process is preferred to be performed by making the ratio of f/d to fall in a range of 30 to 100 MHz/cm, particularly preferably in a region where the d is 1 to 3 cm and the inner pressure of the plasma chamber is 0.1 to 0.5 mbar.

For the process for forming a crystalline silicon series thin film layer, Japanese Laid-open Patent Publication No. 11(1999)-330520 discloses that a crystalline silicon series thin film layer can be formed at a high speed under conditions that a mixture comprising silane series gas and hydrogen gas is used, the inner pressure of the reaction chamber is made to be more than 5 Torr, and the distance between the substrate and the electrode is made to be within 1 cm, and a photoelectric conversion device in which said crystalline silicon series thin film layer is used has a high photoelectric conversion efficiency.

Japanese Patent Publication No. 6(1994)-101458 discloses a method to form a high quality deposited film by using a high frequency power introduction electrode provided with a plurality of holes wherein negative direct current voltage is applied in order to prevent occurrence of spark at the areas of the holes of the electrode.

By the way, it is generally recognized that in the process of forming a deposited film on a substrate by means of high frequency plasma CVD, the film-forming speed (the film deposition rate) can be improved by adopting conditions that the high frequency power introduced is increased, the distance between the substrate and the power introduction electrode is shortened and the high frequency power per a unit volume of the plasma generation space is increased.

However, when the high frequency power per a unit volume of the plasma generation space is increased, the electron density and the ion density in the plasma are increased to entail problems such that the cation is accelerated by virtue of electrostatic attractive force to provide ion bombardment, whereby the atomic arrangement in the bulk is distorted or voids are formed in the film and as a result, it is difficult to form a high quality silicon series thin film. Thus, there is a limitation for the magnitude of the high frequency power introduced in order to uniformly form a high quality film over a large area and this becomes an obstacle when it is intended to increase the film deposition rate (the film-forming speed) in the conventional high frequency plasma CVD process.

Now, the method disclosed in Japanese Patent Publication No. 6(1994)-101458 in which the high frequency power introduction electrode provided with a plurality of holes is used is aimed at preventing occurrence of spark at the areas of the holes of the electrode by applying direct current voltage while being controlled. This document does not touch on the prevention of occurrence of spark which will be occurred between the high frequency power introduction electrode and the earth potential region and the manner of improving the quality of a deposited film formed by controlling the potential during the generation of plasma.

### SUMMARY OF THE INVENTION

In view of the foregoing situation of the prior art, the present invention makes it an object to provide a deposited film-forming apparatus and a deposited film-forming process which enable to form a high quality deposited film having an excellent uniformity at a high deposition rate.

The present invention includes a first aspect and a second aspect.

The first aspect of the present invention provides a deposited film-forming apparatus (this apparatus will be hereinafter referred to as “first deposited film-forming apparatus”) and a deposited film-forming process using said first deposited film-forming apparatus (this process will be referred to as “first deposited film-forming process”).

The second aspect of the present invention provides another deposited film-forming apparatus (this apparatus will be hereinafter referred to as “second deposited film-forming apparatus”) and another deposited film-forming process using said second deposited film-forming apparatus (this process will be referred to as “second deposited film-forming process”).

The first deposited film-forming apparatus in the present invention comprises a power application electrode for forming a deposited film, a high frequency power source connected to said power application electrode, a direct current power source which is connected to said power application electrode and is connected with said high frequency power source in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said power application electrode and said direct current power source such that said arc discharge preventive means is connected with said direct current power source in series connection and is connected with said high frequency power source in parallel connection.

The first deposited film-forming process in the present invention is a process for forming a deposited film on a substrate by using a deposited film-forming apparatus comprising a power application electrode for forming a deposited film, a high frequency power source connected to said power application electrode, a direct current power source which is connected to said power application electrode and is connected with said high frequency power source in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said power application electrode and said direct current power source such that said arc discharge preventive means is connected with said direct current power source in series connection and is connected with said high frequency power source in parallel connection, characterized in that when a symptom of occurrence of arc discharge is detected by said detector, said arc discharge preventive means is actuated.

The second deposited film-forming apparatus in the present invention comprises a plurality of power application electrodes each for forming a deposited film on a substrate, a plurality of high frequency power sources each being connected to one of said plurality of power application electrodes, a direct current power source which is connected to said plurality of power application electrodes through a brunch point of an electric circuit involving said plurality of power application electrodes and is connected with said plurality of high frequency power sources in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said brunch point and said direct current power source such that said arc discharge preventive means is connected with said direct current power source in series connection and is connected with said plurality of high frequency power sources in parallel connection.

The second deposited film-forming process in the present invention is a process for forming a deposited film on a substrate by using a deposited film-forming apparatus comprising a plurality of power application electrodes each for forming a deposited film, a plurality of high frequency power sources each being connected to one of said plurality of power application electrodes, a direct current power source which is connected to said plurality of power application electrodes through a brunch point of an electric circuit involving said plurality of power application electrodes and is connected with said plurality of high frequency power sources in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said brunch point and said direct current power source such that said arc discharge preventive means is connected with said direct current power source in series connection and is connected with said plurality of high frequency power sources in parallel connection, characterized in that when a symptom of occurrence of arc discharge is detected by said detector, said arc discharge preventive means is actuated.

The detector in the present invention is preferred to be a detector capable of detecting a scanty change in the discharge current or the discharge voltage on the basis when the discharge current or the discharge voltage is in a steady state, as a symptom of occurrence of arc discharge.

The arc discharge preventive means in the present invention is preferred to comprise a means capable of cutting off the electrical connection between the direct current power source and the power application electrode. Particularly, the arc discharge preventive means is preferred to comprise a means capable of switching the circuits so as to apply a reverse potential to the power application electrode with respect to the potential possessed by the electrode.

In the present invention, when a deposited film is formed on the substrate. the substrate is preferred to be made such that it has a potential which is higher than that of the power application electrode. Further, it is preferred that the distance between the substrate and the power application electrode is made to fall in a range of 3 mm to 30 mm upon forming a deposited film on said substrate.

In the present invention, it is preferred that the gaseous pressure upon forming a deposited film is made to fall in a range of 100 to 5000 Pa.

In the present invention, it is preferred that the residence time of raw material gas upon forming a deposited film is controlled to fall in a range of 0.01 to 10 seconds

In the present invention, it is preferred that the density of the high frequency power upon forming a deposited film is controlled to fall in a range of 0.01 to 2 W/cm³.

In the present invention, it is preferred that the film formation using the deposited film-forming apparatus in the first or second aspect is performed in a manner wherein raw material gas is introduced into said apparatus and simultaneously with this, a prescribed high frequency power from the high frequency power source and a prescribed direct current voltage from the direct current power source are supplied to the power application electrode to generate a plasma, whereby said raw material gas is decomposed to cause the formation of a deposited film on a substrate positioned in said apparatus. The deposited film formed can include a silicon series deposited film. The present invention provides a deposited film formed in this way.

The features and advantages of the present invention will be detailed later with reference to the drawings.

### BRIEF DESCRIPTION OF THE DRAWINGS

FIG. 1 is a schematic diagram illustrating the constitution of an example of a deposited film-forming apparatus in the present invention.

FIG. 2 is a schematic diagram illustrating the constitution of a deposited film-forming apparatus concerning an example of the present invention.

FIG. 3 is a schematic cross-sectional view illustrating an example of a photovoltaic element in which the present invention can be applied.

FIG. 4 a schematic diagram illustrating the constitution of a deposited film-forming apparatus concerning a comparative example.

FIG. 5 a schematic diagram illustrating the constitution of a deposited film-forming apparatus concerning another comparative example.

FIG. 6 is a schematic cross-sectional view illustrating another example of a photovoltaic element in which the present invention can be applied.

FIG. 7 is a schematic diagram illustrating the constitution of another example of a deposited film-forming apparatus in the present invention.

FIG. 8 is a schematic diagram illustrating the constitution of a further example of a deposited film-forming apparatus in the present invention.

FIG. 9 is a schematic diagram illustrating the constitution of a deposited film-forming apparatus concerning another example of the present invention.

FIG. 10 is a schematic cross-sectional view illustrating a further example of a photovoltaic element in which the present invention can be applied.

FIG. 11 is a schematic diagram illustrating the constitution of a deposited film-forming apparatus concerning a further comparative example.

FIG. 12 a schematic diagram illustrating the constitution of a deposited film-forming apparatus concerning a still further comparative example.

FIG. 13 is a schematic cross-sectional view illustrating a still further example of a photovoltaic element in which the present invention can be applied.

### DETAILED DESCRIPTION OF THE INVENTION AND PREFERRED EMBODIMENTS

In the following, the present invention will be detailed.

[First Aspect]

Description will be made of the first aspect of the present invention.

The present inventors conducted extensive studies through experiments in order to solve the shortcomings in the prior art and to achieve the foregoing object. As a result, there was obtained a finding that in the deposited film-forming apparatus in that a parallel connection body in which the high frequency power source and the direct current power source are connected in parallel connection is connected to the power introduction electrode for forming a deposited film, by adopting a constitution comprising an arc discharge-detecting means which is connected with the direct current power source in series connection and is connected with the high frequency power source in parallel connection, it is possible to make the deposited film-forming apparatus such that a more large frequency power can be introduced and a high quality deposited film having an excellent uniformity can be efficiently formed on a substrate at a high deposition rate. The present invention has been accomplished based on this finding.

Thus, the first aspect of the present invention provides an improved deposited film-forming apparatus and a deposited film-forming process using said deposited film-forming apparatus.

Particularly, the deposited film-forming apparatus in the first aspect of the present invention comprises a power application electrode for forming a deposited film positioned in a film-forming vessel, a high frequency power source connected to said power application electrode, a direct current power source which is connected to said power application electrode and is connected with said high frequency power source in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said power application electrode and said direct current power source such that said arc discharge preventive means is connected with said direct current power source in series connection and is connected with said high frequency power source in parallel connection.

The deposited film-forming process in the first aspect of the present invention is a process for forming a deposited film on a substrate by using aforesaid deposited film-forming apparatus, characterized in that when a symptom of occurrence of arc discharge is detected by said detector, said arc discharge preventive means is actuated.

The apparatus constitution in the first aspect of the present invention comes into play as will be described below.

In the process of forming a deposited film on a substrate positioned in the vacuum vessel by means of high frequency plasma CVD by introducing raw material gas into said vacuum vessel, by making the power application electrode and the substrate such that they are close to each other, increasing the high frequency power introduced, increasing the gas pressure of the raw material gas in the vacuum vessel, or controlling the residence time of the raw material gas in the vacuum vessel so that the raw material gas is not depleted in the vacuum vessel while the raw material gas being sufficiently decomposed, it is considered that the plasma density per a unit volume of the discharge space will be increased to form reactive active species, which contribute to deposit a deposited film on the substrate, at a high density, and this will make to form a deposited film on the substrate at a high deposition rate (high film-forming speed).

As the conditions to form a deposited film on a substrate at a high deposition rate by means of high frequency plasma CVD, for instance in the case where said deposited film is a silicon series deposited film, there can be mentioned the following conditions. From viewpoints that raw material gas can be efficiently decomposed and a high frequency power can be uniformly introduced into the plasma generation space from a large area power application electrode, it is preferred to use a high frequency power with a frequency in a range of 20 to 500 MHz or preferably in a range of 30 to 150 MHz. The distance between the substrate and the power application electrode is preferred to be made to fall in a range 3 to 30 mm. The gas pressure in the plasma generation space (corresponding to the film-forming space) is preferred to be made to fall in a range of 100 to 5000 Pa. By adopting these conditions, it is possible to sufficiently form the reactive active species in the plasma generation space without depleting the raw material gas.

In addition, when the volume of the discharge space (the plasma generation space) in which a plasma is generated is made to be V(cm³), the flow rate of the raw material gas is made to be Q[cm³/min(normal)], and the gas pressure in the discharge space is made to be P(Pa), the residence time t(second) of the raw material gas in the discharge space which is defined by the equation t=592×V×P/Q is preferred to fall in a range of 0.01 to 10 seconds. By adopting this condition, the radical density in the plasma can be controlled as desired and a silicon series deposited film whose defect density is slight and having excellent characteristics can be formed on a substrate at a high deposition rate.

Now, it is considered that by shortening the distance between the power application electrode and the substrate or increasing the output of the high frequency power introduced, the electron density in the plasma generated will be increased and along with this, the quantity of cation will be increased. Separately, it is considered that the cation will behaves such that it is accelerated by virtue of electrostatic attractive force in the sheath region of the discharge space (the plasma generation space) toward the substrate side to provide ion bombardment, where the atomic arrangement in the bulk is distorted or voids are formed in the film, and this makes it difficult to form a high quality silicon series deposited film.

Here, by establishing a circuit which overlaps a direct current potential with the high frequency power to lower the potential of the power application electrode, it becomes possible that a certain quantity of the cation generated in the plasma is positively induced toward the power application electrode side, and because of this, it becomes possible to refrain the ion bombardment to the substrate and to form a high quality silicon series deposited film. In addition, it becomes possible to prevent a non-dense deposited film from being formed and to form a dense deposited film having an excellent uniformity. This makes it possible to form a high quality deposited film excelling in adhesion with the backing and also in environmental resistance. It is considered that these effects are provided as a result of lowering the potential of the power application electrode than that of the substrate.

Further, by making the gas pressure in the plasma generation space (corresponding to the film-forming space) to fall in a range of 100 to 5000 Pa as above described, it is considered that the occasion for the ion in the plasma to collide with other ions or active species is increased and as a result, not only the ion impact force is decreased but also the ion quantity is diminished. Thus, it is expected that the ion bombardment is relatively reduced.

Now, in the case where a high frequency power with a high density is introduced under high pressure condition, the collision reaction of a decomposed product with the raw material gas is promoted, where fine powder is likely generated in the plasma generation space. The fine powder is charged by virtue of electrostatic attractive force at a stage when it is in a cluster form. Because the charged fine powder is liable to stay in the plasma, where the charged fine powder in the plasma will be grown further. Such fine powder formed in this way will be taken into a film deposited on the substrate during the reaction process, where the resulting deposited film will be inferior in terms of the characteristics.

Separately, when said fine powder is deposited on the internal components of the apparatus, the operation efficiency of the apparatus is deteriorated. This results in raising the production cost of a device product.

Particularly, in the case where a high frequency power with a frequency in the foregoing range (that is, in a range of 20 to 500 MHz) is used, to follow the charged fine power cannot be readily carried out and therefore, it is difficult to remove the fine powder from the plasma generation space.

Here, the plasma potential can be controlled by overlapping the direct current potential with the high frequency power to lower the potential of the power application electrode. It is considered that this makes it possible to remove the charged fine power from the plasma generation space.

However, in the case where it is intended to realize the foregoing effects by introducing a large high frequency power into the power application electrode, and overlapping the direct current potential to the power application electrode under the foregoing conditions which enable to form a deposited film at a high deposition rate, there will be entailed a problem such that occurrence of arch discharge is induced between the deposited film-forming surface and the power application electrode and this makes it difficult to maintain the plasma in a stable state and to form a high quality deposited film. When the formation of a deposited film is performed under such unstable plasma, uneven region is formed in the film and this makes the resulting deposited film to be inferior in terms of the uniformity, adhesion, and durability.

Now, in the present invention, in the deposited film-forming apparatus in that the parallel connection body in which the high frequency power source and the direct current power source are connected in parallel connection is connected to the power introduction electrode, the constitution comprising the arc discharge-detecting means which is connected with the direct current power source in series connection and is connected with the high frequency power source in parallel connection is adopted, wherein when a symptom of occurrence of arc discharge is detected by the arc discharge-detecting means, the arc is died out. This enables to prevent such problem as above described from being entailed, to maintain the plasma in a stable state, and to efficiently form a high quality deposited film. As the arc discharge-detecting means, there is typically used an arc discharge-detecting detector which functions to detect said symptom of occurrence of arc discharge.

The “symptom of arc discharge” in the present invention includes, for example, a scanty change in the discharge current or the discharge voltage on the basis when the discharge current or the discharge voltage is in a steady state. In this case, the arc discharge-detecting detector operates to monitor the discharge current or the discharge voltage, when a scanty change is occurred in the discharge current or the discharge voltage on the basis when the discharge current or the discharge voltage is in a steady state, the arc discharge-detecting detector detects said scanty change as a symptom of occurrence of arc discharge.

As the method to prevent the occurrence of arc discharge, there can be mentioned a method of momentarily cutting off the electrical connection between the direct current power source and the power application electrode, a method of switching the circuit so as to apply a reverse potential to the power application electrode with respect to the potential possessed by the electrode. In the deposited film-forming apparatus of the present invention, there is adopted an arc discharge preventive means for preventing the occurrence of arc discharge. The arc discharge preventive means is actuated when aforesaid symptom of occurrence of arc discharge is detected by the arc discharge-detecting detector. The arc discharge preventive means may comprise a switching mechanism to momentarily cut off the electrical connection between the direct current power source and the power application electrode or a switching mechanism to switch the circuit so as to apply a reverse potential to the power application electrode with respect to the potential possessed by the electrode.

In the case where the arc discharge-detecting detector is arranged such that it takes a series connection with the direct current power source and also a series connection with the high frequency power source or in the case where the arc discharge-detecting detector is arranged such that it takes a parallel connection with the direct current power source and a series connection with the high frequency power source, when the arc discharge preventive means is actuated, there will be occurred a problem such that the high frequency power becomes incapable of being steadily introduced into the power application electrode or the arc discharge-detecting detector becomes incapable of detecting the symptom of occurrence of arc discharge.

Therefore, in order for the plasma to be maintained in a stable state without the occurrence of such problem even when a large high frequency power is introduced into the power application electrode and a large direct current potential is overlapped with the power application electrode, it is necessary that the arc discharge preventive means is arranged such that it is connected with the direct current power source in series connection and is connected with the high frequency power source in parallel connection, likewise it is necessary that the arc discharge-detecting detector is arranged such that it is connected with the direct current power source in series connection and is connected with the high frequency power source in parallel connection.

The previously described effects of the present invention are exhibited particularly when the high frequency power density upon forming the deposited film is more than 0.01 W/cm³. Thus, the formation of the deposited film is preferred to be performed under this condition. However, the high frequency power density exceeds 2 W/cm³, it becomes difficult to prevent the occurrence of fine powder. Therefore, it is preferred that the high frequency power density is controlled to be in a range of less than 2 W/cm³.

It is preferred that the deposited film-forming process is performed by using a roll-to-roll process. In the roll-to-roll process, a prolonged web substrate having a desired width is continuously moved in the longitudinal direction so as to sequentially pass through a plurality of deposited film-forming vessels arranged along with a pass way of said web substrate to move while forming a desired deposited film on the web substrate by each deposited film-forming vessel. In the roll-to-roll process, the film formation is performed while maintaining a plasma in each of the plurality of deposited film-forming vessels and therefore, it is difficult to make the web substrate have a different for every deposited film-forming vessel. Thus, it is preferred to adopt a method in that the plasma potential is controlled by making the web substrate side to be an earth potential.

In the case where the web substrate is an electrically conductive web substrate, it is possible to make the electrically conductive web substrate to serve also as the electrically earthed electrode arranged at a position to oppose to the power application electrode.

In the following, description will be made of the constituents of the deposited film-forming apparatus in the first aspect of the present invention.

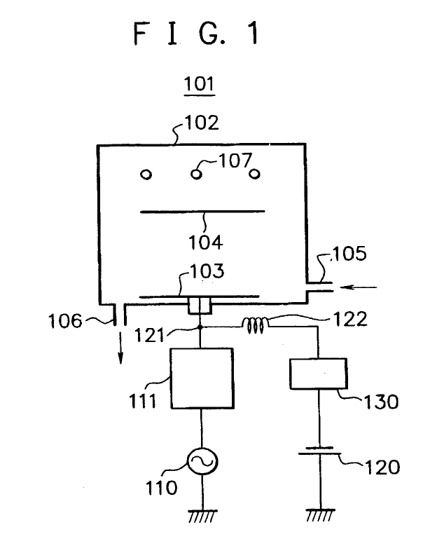

FIG. 1 is a schematic diagram illustrating a high frequency plasma CVD apparatus as an example of the deposited film-forming apparatus in the first aspect of the present invention.

In FIG. 1, reference numeral 101 indicates a high frequency plasma CVD apparatus having a film-forming vessel 102 whose inside is capable of being maintained in a vacuumed state. Reference numeral 103 indicates a power application electrode arranged in the inside of the film-forming vessel 102 so as to electrically isolate from the film-forming vessel.

Reference numeral 104 indicates a substrate retained on a substrate holder (not shown) in the film-forming vessel 102, and reference numeral 107 a lamp heater arranged at a position on the opposite side of the substrate 104 with respect to the power application electrode 103. The film-forming vessel 102 is provided with a gas introduction pipe 105 for introducing raw material gas into the film-forming vessel. The film-forming vessel 102 is also provided with an exhaust pipe 106 connected to a vacuum pump (not shown). Reference numeral 110 indicates a high frequency power source which is connected to the power application electrode 103 through a matching box 111. A prescribed high frequency power from the high frequency power source 110 is applied to the power application electrode 103 while being adjusted by the matching box 111.

Reference numeral 120 indicates a direct current power source which is connected to the power application electrode 103 through an arc discharge-detecting detector 130 and a choke coil 122. Reference 121 indicates a brunch point between the circuit of the high frequency power source 110 and the circuit of the direct current power source 120.

The arc discharge-detecting detector 130 includes an arc discharge preventive means (not shown).

The electric system of the high frequency plasma CVD apparatus shown in FIG. 1 is essential to have a constitution containing a parallel connection body in which the high frequency power source 110 and the direct current power source 120 are connected in parallel connection is connected to the power application electrode 103 and wherein the arc discharge-detecting detector 130 is connected with the direct current power source 120 in series connection and is connected with the high frequency power source 110 in parallel connection. As long as this condition is satisfied, it is possible that the brunch point 121 is situated at a desired position on the circuit as shown in FIG. 1 or it is situated in the matching box 111.

The introduction of the raw material gas into the film-forming vessel 102 is performed through the gas introduction pipe 105 as shown in FIG. 1. However, in the case where the distance between the power application electrode 103 and the substrate 104 is small, it is possible for the power application electrode 103 to be structured to have a an inner space capable of allowing the raw material gas to be introduced therein and to have a plurality of holes on the substrate side which allows said raw material gas to be supplied toward the substrate through said plurality of holes.

The formation of a deposited film on the substrate 104 in the high frequency plasma CVD apparatus 101 shown in FIG. 1 is performed by applying a prescribed high frequency power from the high frequency power source 110 to the power application electrode 103 to generate glow discharge thereby to decompose the raw material gas in the film-forming vessel 102 while overlapping a prescribed direct current potential to the power application electrode 103 by the direct current power source 120.

[Second Aspect]

Description will be made of the second aspect of the present invention.

The present inventors conducted extensive studies through experiments in order to solve the shortcomings in the prior art and to achieve the foregoing object.

As a result, in the deposited film-forming apparatus having a plurality of power application electrodes for forming a deposited film, a plurality of high frequency power sources each being connected to one of said plurality of power application electrodes, a direct current power source which is connected to said plurality of power application electrodes through a brunch point of electric circuit and is connected with said plurality of high frequency power sources in parallel connection, there was obtained a finding that by adopting a constitution comprising an arc discharge-detecting means (comprising a detector for detecting a symptom of occurrence of arc discharge and an arc discharge preventive means) in the electric circuit through which the direct current power source and the high frequency power sources are connected, it is possible to make the deposited film-forming apparatus such that a more large frequency power can be introduced and a high quality deposited film having an excellent uniformity can be efficiently formed on a substrate at a high deposition rate. The present invention has been accomplished based on this finding.

Thus, the second aspect of the present invention provides an improved deposited film-forming apparatus and a deposited film-forming process using said deposited film-forming apparatus.

Particularly, the deposited film-forming apparatus in the second aspect of the present invention comprises a plurality of power application electrodes each for forming a deposited film positioned in a film-forming vacuum vessel, a plurality of high frequency power sources each being connected to one of said plurality of power application electrodes, a direct current power source which is connected to said plurality of power application electrodes through a brunch point of an electric circuit through which said plurality of high frequency power sources and said plurality of power application electrodes are connected and is connected with said plurality of high frequency power sources in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said brunch point and said direct current power source such that said arc discharge preventive means is connected with said direct current power source in series connection and is connected with said plurality of high frequency power sources in parallel connection.

The deposited film-forming process in the second aspect of the present invention is a process for forming a deposited film on a substrate by using aforesaid deposited film-forming apparatus, characterized in that when a symptom of occurrence of arc discharge is detected by said detector, said arc discharge preventive means is actuated.

The apparatus constitution of the second aspect of the present invention affords actions and advantages as will be described below, in addition to those previously described in the first aspect of the present invention.

A principal feature of the apparatus constitution of the second aspect of the present invention is that the direct current power source is connected to the plurality of power application electrodes through brunch points of electric circuits through which the plurality of high frequency power sources and the plurality of power application electrodes are connected and the direct current power source is connected with the plurality of high frequency power sources in parallel connection and wherein the arc discharge-detecting means is arranged between said brunch points and the direct current power source.

According to the apparatus constitution of the second aspect of the present invention, a more large frequency power can be introduced and a high quality deposited film having an excellent uniformity can be efficiently formed on a substrate at a high deposition rate, as above described. In addition, although the plurality of power application electrodes and the plurality of high frequency power sources are used, it is necessary to increase the number of the direct current power source. This is advantageous in that the apparatus cost can be reduced and the apparatus scale can be diminished. Further, the direct current power source is connected to the plurality of power application electrodes through brunch points of electric circuits through which the plurality of high frequency power sources and the plurality of power application electrodes are connected and is connected with the plurality of high frequency power sources in parallel connection. Thus, one direct current power source effects for the plurality of power application electrodes at the same time. Therefore, the plurality of power application electrodes involved can be readily made to be the same in terms of the potential state. This makes the plasmas generated in a plurality of discharge spaces have an improved uniformity.

For the electric connection circuit to connect the high frequency power source and the direct current power source with the power application electrode in parallel connection, it is possible to adopt a constitution in that a parallel connection body in which the high frequency power source and the direct current power source are collected in parallel connection is connected with the power application electrode. Besides, it is possible to adopt a constitution in that the high frequency power source and the direct current power source are separately connected with the power application electrode in parallel connection.

In the following, description will be made of the constituents of the deposited film-forming apparatus in the second aspect of the present invention.

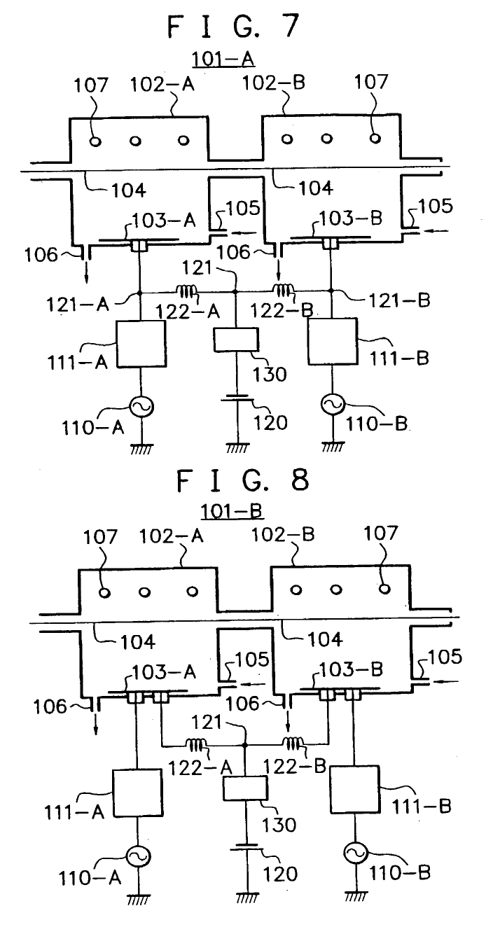

FIG. 7 is a schematic diagram illustrating a high frequency plasma CVD apparatus of roll-to-roll system, as an example of the deposited film-forming apparatus in the second aspect of the present invention. In FIG. 7, reference numerals which are the same as those in FIG. 1 indicate the same constituents indicated by those reference numerals in FIG. 1.

In FIG. 7, reference numeral 101-A indicates a principal part of a high frequency plasma CVD apparatus of roll-to-roll system. Reference numerals 102-A and 102-B indicate respectively a film-forming vessel whose inside is capable of being maintained In a vacuumed state. Reference numerals 103-A and 103-B indicate respectively a power application electrode arranged in the inside of the film-forming vessel (102-A, 102-B) so as to electrically isolate from the film-forming vessel. Reference numeral 104 indicates a prolonged substrate (a web substrate) which is transported from a direction on the left side to a direction on the right side (in the figure) while being retained by a support member (not shown). In the film-forming vessel (102-A, 102-B), a lamp heater 107 is arranged at a position on the opposite side of the substrate 104 with respect to the power application electrode (103-A, 103-B). The film-forming vessel (102-A, 102-B) is provided with a gas introduction pipe 105 for introducing raw material gas into the film-forming vessel. The film-forming vessel (102-A, 102B) is also provided with an exhaust pipe 106 connected to a vacuum pump (not shown). Reference numerals 110-A and 110-B indicate respectively a high frequency power source which is connected to the power application electrode (103-A, 103-B) through a matching box (111-A, 111-B). A prescribed high frequency power from the high frequency power source (110-A, 110-B) is applied to the power application electrode (103-A, 103-B) while being adjusted by the matching box (111-A, 111-B). Reference numeral 120 indicates a direct current power source which is connected to a brunch point 121 through an arc discharge-detecting detector 130, then is connected to the power application electrodes 103-A and 103-B via choke coils 122-A and 122-B and brunch points 121-A and 121-B. The arc discharge-detecting detector 130 includes an arc discharge preventive means (not shown).

The electric system of the high frequency plasma CVD apparatus shown in FIG. 7 is essential to have an constitution in that a parallel connection body in which the high frequency power source (110-A, 110-B) and the direct current power source 120 are connected in parallel connection is connected to the power application electrode (103-A, 103-B) and wherein the arc discharge-detecting detector 130 is connected with the direct current power source 120 in series connection and is connected with the high frequency power source (110-A, 110-B) in parallel connection. As long as this condition is satisfied, it is possible that the brunch point (121-A, 121-B) is situated at a desired position on the circuit as shown in FIG. 7 or it is situated in the matching box (111-A, 111-B). The constitution in FIG. 7 in that the high frequency power source (110-A, 110-B) and the direct current power source 120 are connected in parallel connection and this parallel connection body is connected to the power application electrode (103-A, 103-B) may be replaced by such a constitution as shown in FIG. 8 in that the high frequency power source (110-A, 110-B) and the direct current power source 120 are separately and independently connected to the power application electrode (103-A, 103-B).

The introduction of the raw material gas into the film-forming vessel (102-A, 102B) is performed through the gas introduction pipe 105 as shown in FIG. 7. However, in the case where the distance between the power application electrode (103-A, 103-B) and the substrate 104 is small, it is possible for the power application electrode (103-A, 103-B) to be structured to have a an inner space capable of allowing the raw material gas to be introduced therein and to have a plurality of holes on the substrate side which allows said raw material gas to be supplied toward the substrate through said plurality of holes.

The formation of a deposited film on the substrate 104 in the high frequency plasma CVD apparatus shown in FIG. 7 is performed by applying a prescribed high frequency power from the high frequency power source (110-A, 110-B) to the power application electrode (103-A, 103-B) to generate glow discharge thereby to decompose the raw material gas in the film-forming vessel (102-A, 102-B) while overlapping a prescribed direct current potential to the power application electrode (103-A, 103-B) by the direct current power source

In the following, the features and advantages of present invention will be described in more detail with reference to examples. It should be understood that these examples are only for the illustrative purposes and are not intended to restrict the scope of the present invention.

In the following examples, the features and advantages of present invention will be explained by forming a silicon series deposited film and preparing a photovoltaic element. The deposited film formed by the present invention is not limited to such silicon series deposited film.

In the following, Examples 1 and 2 are relating to the first aspect of the present invention. Similarly, Examples 3 and 4 are relating to the second aspect of the present invention.

### EXAMPLES OF THE FIRST ASPECT

### Example 1

### Examples 1-1 to 1-4

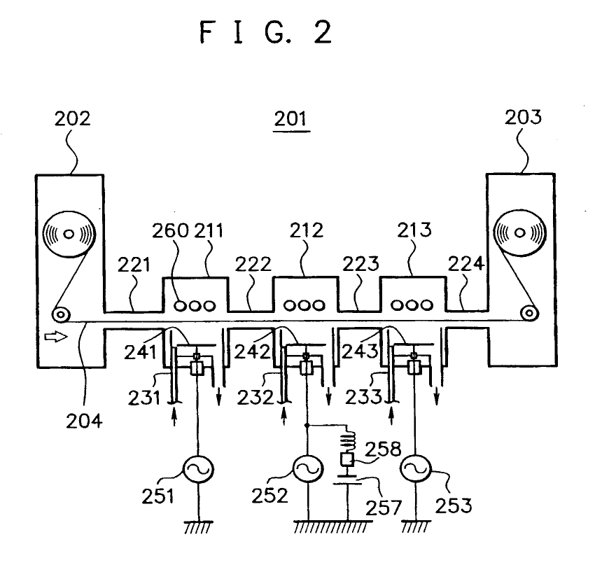

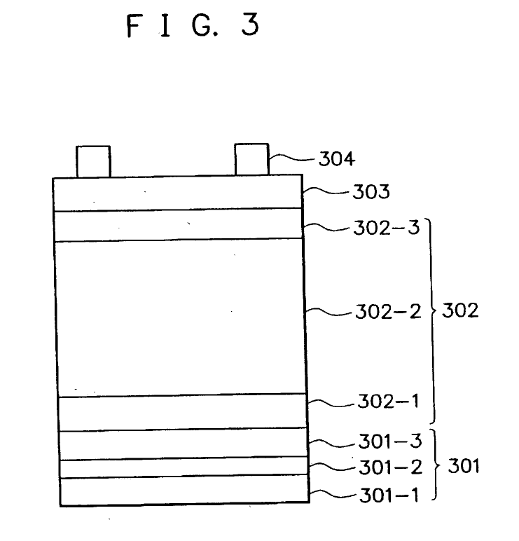

In this example, a photovoltaic element having such configuration as shown in FIG. 3 was prepared by forming deposited films using a deposited film-forming apparatus 201 shown in FIG. 2 of the present invention.

FIG. 2 is a schematic diagram illustrating a high frequency plasma CVD apparatus of the roll-to-roll system, as an example of the deposited film-forming apparatus in the first aspect of the present invention.

The high frequency plasma CVD apparatus 201 shown in FIG. 2 comprises a substrate delivery vacuum vessel 202, film-forming vacuum vessels 211-213, and a substrate take-up vacuum vessel 203 which are communicated with each other through gas gates 221-224. A pay-out bobbin having a web substrate 204 wound thereon is positioned in the substrate delivery vacuum vessel 202. The web substrate 204 is paid out from the pay-out bobbin and delivered from the substrate delivery vacuum vessel 202, followed by passing through the gas gate 221, the film-forming vacuum vessel 211, the gas gate 222, the film-forming vacuum vessel 212, the gas gate 223, the film-forming vacuum vessel 213 and the gas gate 224 to enter the substrate take-up vacuum vessel 203 where the beginning portion of the web substrate 204 is fixed to and wound a take-up bobbin positioned in the substrate take-up vacuum vessel 203. In the film-forming operation, the web substrate 204 is moved from the substrate delivery vacuum vessel 202 to the substrate take-up vacuum vessel 203 where the web substrate 204 is wound on the take-up bobbin in the substrate take-up vacuum vessel 203.

The film-forming vacuum vessels 211-213 have respectively a deposition chamber having a plasma generation region. Each deposition chamber is structured to have a discharge space in which a plasma is generated, whose top is defined by the substrate 204, whose bottom is defined by a plate-shaped power application electrode (241, 242, 243) and whose circumference is circumscribed by a discharge plate arranged so as to surround the power application electrode.

Each of film-forming vacuum vessels 211-213 is provided with a gas introduction pipe (231, 232, 233) for introducing dilution gas or/and raw material gas and is also provided with an exhaust pipe connected to a vacuum pump (not shown). In each of film-forming vacuum vessels 211-213, there is provided a lamp heater 260 for heating the substrate 204.

By applying a high frequency power from a high frequency power source (251, 252, 253) to the plate-shaped power application electrode (241, 242, 243) in the deposition chamber of the film-forming vacuum vessel (211, 212, 213) to generate glow discharge, whereby raw material gas introduced through the gas introduction pipe (231, 232, 233) is decomposed to form a deposited film as a semiconductor layer on the substrate 204.

The power application electrode (241, 242, 243) is opposed to the substrate 204, where a height-adjusting mechanism (not shown) is provided. By this height-adjusting mechanism, it is possible to change the distance between the substrate 204 and the power application electrode (241, 242, 243) and at the same time, it is possible to change the volume of the discharge space.

The film-forming vacuum vessel 212 containing the factors of the present invention has a circuit constitution on the pathway between the high frequency power source 252 and the power application electrode 242, in which a direct current potential is overlapped to the high frequency power by a direct current power source 257. The film-forming vacuum vessel 212 also has an arc discharge-detecting detector 258 (including an arc discharge preventive means) which is connected with the direct current power source 257 in series connection and is connected with the high frequency power source 252 in parallel connection. The arc discharge-detecting detector 258 functions to detect a symptom of occurrence of arc discharge. When a symptom of occurrence of arc discharge is detected by the arc discharge-detecting detector 258, the arc discharge preventive means is actuated to prevent the occurrence of arc discharge. It is appropriate that at least the arc discharge preventive means which is included in the arc discharge-detecting detector 258 is connected between the direct current power source 257 and the power application electrode 242 such that it is connected with the direct current power source 257 in series connection and is connected with the high frequency power source 252 in parallel connection.

FIG. 3 is a schematic cross-sectional view illustrating an example of a photovoltaic element containing a deposited film formed according to the present invention, which is prepared in this example.

In FIG. 3, reference numeral 301 indicates a substrate, reference numeral 302 a semiconductor layer, reference numeral 303 a transparent and electrically conductive layer, and reference numeral 304 a collecting electrode. The substrate 301 comprises a base member 301-1, a metal layer 301-2, and a first transparent and electrically conductive layer 301-3. The semiconductor layer 302 comprises an n-type amorphous semiconductor layer 302-1, an i-type crystalline phase-containing semiconductor layer 302-2, and a p-type crystalline phase-containing semiconductor layer 302-3. Thus, the photovoltaic element shown in FIG. 3 is a so-called p-i-n type single cell photovoltaic element.

There was prepared a p-i-n type single cell photovoltaic element shown in FIG. 3 in the following manner, using the apparatus shown in FIG. 2.

1. Provision of Web Substrate:

As the web substrate 204, there was provided a substrate roll comprising a well-cleaned web substrate made of stainless steel (SUS430BA) (having a thickness of 0.125 mm, a width of 50 cm and a length of 200 m) having a 100 nm thick Ag thin film (as a metal layer 301-2) and a 1.2 μm thick ZnO thin film (as a first transparent and electrically conductive layer 301-3) formed in this order thereon by means of a conventional roll-to-roll type sputtering apparatus (not shown) which is wound on a pay-out bobbin.

2. Preparation of Photovoltaic Element:

The pay-out bobbin having the web substrate 204 wound thereon was positioned in the substrate delivery vacuum vessel 202 of the apparatus shown in FIG. 2. From the pay-out bobbin, the web substrate 204 was paid out and delivered from the substrate delivery vacuum vessel 202, followed by passing through the gas gate 221, the film-forming vacuum vessel 211, the gas gate 222, the film-forming vacuum vessel 212, the gas gate 223, the film-forming vacuum vessel 213 and the gas gate 224 to enter the substrate take-up vacuum vessel where the beginning portion of the web substrate 204 was fixed and wound on the substrate take-up bobbin. And the transportation system of the web substrate 204 was adjusted so that the web substrate could be continuously and smoothly transported from the substrate delivery vacuum vessel 202 to the take-up vacuum vessel 203 without being distorted or warped.

Then, each of the substrate delivery vacuum vessel 202, the film-forming vacuum vessels 212-213, and the take-up vacuum vessel 203 was evacuated until the inner pressure reached about 1.0 mPa by means of the exhaustion system comprising the vacuum pump (not shown).

While continuing this evacuation, raw material gas and dilution gas were introduced into the film-forming vacuum vessels 211, 212 and 213 through the gas introduction pipes 231, 232 and 233, simultaneously with this, H₂ gas as a gate gas was flown into the gas gates 221, 222, 223 and 224 at a flow rate of 500 cm³/min (normal). While maintaining this state, the exhausting performance of each exhaustion system was controlled to adjust the gas pressure in each of the film-forming vacuum vessels 211, 212 and 213 to have a prescribed value. The film-forming conditions in each of the film-forming vacuum vessels 211, 212 and 213 are shown in Table 1.

When the gas pressure in each of the film-forming vacuum vessels 211, 212 and 213 became stable at the prescribed value, the web substrate 204 was started moving at a prescribed transportation speed from the substrate delivery vacuum vessel 202 toward the substrate take-up vacuum vessel 203.

Then, a high frequency power from each of the high frequency power sources 251, 252 and 253 was applied to each of the power application electrodes 241, 242 and 243 in each of the film-forming vacuum vessels 211, 212 and 213 to generate glow discharge in the deposition chamber in each of the film-forming vacuum vessels 211, 212 and 213, whereby sequentially and continuously forming an n-type amorphous semiconductor layer 302-1 having a thickness of 30 nm in the film-forming vacuum vessel 211, an i-type crystalline phase-containing semiconductor layer 302-2 having a thickness of 1.5 μm in the film-forming vacuum vessel 212, and a p-type crystalline phase-containing semiconductor layer 302-3 having a thickness of 10 nm in the film-forming vacuum vessel 213 to form a p-i-n single cell semiconductor layer 302 on the web substrate 204. Thus, there was obtained a photovoltaic element in a web form.

Here, in the deposition chamber of the film-forming vacuum vessel 211, a high frequency power whose frequency is 13.56 MHz and having a power density of 5 mW/cm³ was introduced from the power application electrode 241 (comprising a metal electrode made of aluminum). Similarly, in the deposition chamber of the film-forming vacuum vessel 213, a high frequency power whose frequency is 13.56 MHz and having a power density of 30 mW/cm³ was introduced from the power application electrode 243 (comprising a metal electrode made of aluminum). And in the deposition chamber of the film-forming vacuum vessel 212, a high frequency power whose frequency is 60 MHz and having a power density of 400 mW/cm³ was introduced from the power application electrode 242 (comprising a metal electrode made of aluminum). Simultaneously with this, in the deposition chamber of the film-forming vacuum vessel 212, a direct current potential from the direct current power source 257 was overlapped to the high frequency power. As shown in Table 2, the operation to overlap the direct current potential to the high frequency power was conducted separately for four cases (Examples 1-1 to 1-4), specifically by changing the direct current potential of the power application electrode 242 to −50 V, −100 V, −200 V, and −300 V against the earth potential.

In this way, there were prepared a web-shaped photovoltaic element of Example 1-1, a web-shaped photovoltaic element of Example 1-2, a web-shaped photovoltaic element of Example 1-3, and a web-shaped photovoltaic element of Example 1-4. Each of these web-shaped photovoltaic elements was cut and processed by using a continuous module-making apparatus, to obtain a plurality of solar cell modules having a size of 36 cm×22 cm.

### Comparative Example 1

### Comparative Examples 1-1 to 1-4

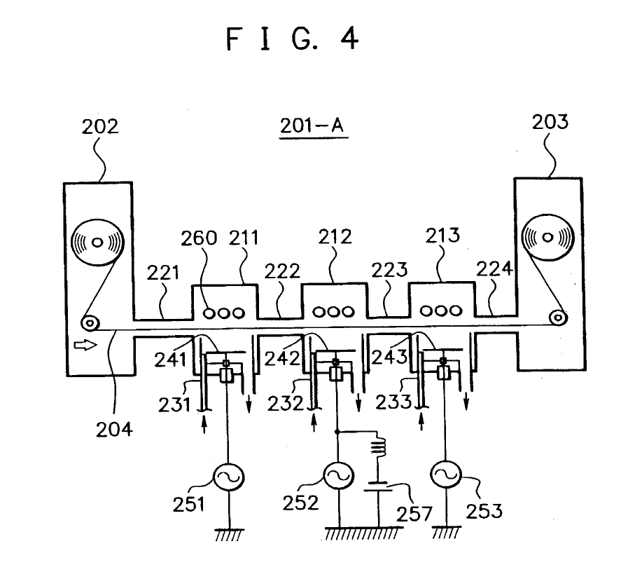

The procedures of Example 1 were repeated except for using a high frequency plasma CVD apparatus 201-A shown in FIG. 4 whose constitution is the same as that of high frequency plasma CVD apparatus 201 shown in FIG. 2 except for not having the arc discharge-detecting detector 258, wherein in the film-forming vacuum vessel 212, as well as in Example 1, as shown in Table 2, the operation to overlap the direct current potential to the high frequency power was conducted separately for four cases (Comparative Examples 1-1 to 1-4), specifically by changing the direct current potential of the power application electrode 242 to −50 V, −100 V, −200 V, and −300 V against the earth potential. In this way, there were prepared a web-shaped photovoltaic element of Comparative Example 1-1, a web-shaped photovoltaic element of Comparative Example 1-2, a web-shaped photovoltaic element of Comparative Example 1-3, and a web-shaped photovoltaic element of Comparative Example 1-4.

The state of the plasma in the deposition chamber in the film-forming vacuum vessel 212 in Example 1 (that is, Examples 1-1 to 1-4) was stable. On the other hand, for the state of the plasma in the deposition chamber of the film-forming vacuum vessel 212 in Comparative Example 1 (that is, Comparative Examples 1-1 to 1-4), it was observed that as the direct current potential of the power application electrode 242 was made to be smaller, namely, as the direct current voltage component to be overlapped was increased, the spark occurring frequency was increased.

Each of the web-shaped photovoltaic elements obtained in the above was cut and processed by using the continuous module-making apparatus, to obtain a plurality of solar cell modules having a size of 36 cm×22 cm.

### Comparative Example 1-5

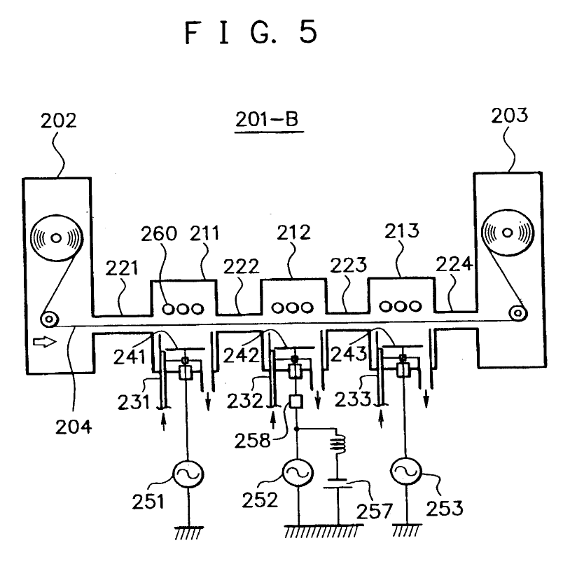

Using a high frequency plasma CVD apparatus 201-B shown in FIG. 5 whose constitution is the same as that of high frequency plasma CVD apparatus 201 shown in FIG. 2 except that the arc discharge-detecting detector 258 is connected with the direct current power source 257 in series connection and is connected with the high frequency power source 252 in series connection, the formation of a p-i-n single cell semiconductor layer 302 on the web substrate 204 was tried in the same manner as in Example 1. However, in the film-forming vacuum vessel 212, the arc discharge preventive means was actuated quite frequently to disconnect the electric connection between the power application electrode and the high frequency power source and to quite frequently cut off the high frequency power, where the plasma could not be stably maintained.

### Evaluation

1. Each of the solar cell modules of Examples 1-1 to 1-4 and Comparative Examples 1-1 to 1-4 was evaluated with respect to the adhesion of the semiconductor layer with the substrate in accordance with the lattice pattern tape method prescribed in JIS standard-K5400 8.5.1(cut clearance interval: 1 mm; number of lattices: 100). The evaluated results are collectively shown in Table 2.

2. On the surface of the semiconductor layer of each of the web-shaped photovoltaic elements of Examples 1-1 to 1-4 and Comparative Examples 1-1 to 1-4, 100 transparent electrodes (comprising a transparent and electrically conductive layer) having a size of 1 cm×1 cm were spacedly formed at an equal interval, followed by forming a collecting electrode on each transparent electrode, to form 100 subcells spacedly arranged. For each of the 100 subcells thus formed in each case, the photoelectric conversion efficiency thereof was measured by using a solar simulator (AM 1.5, 100 mW/cm²). Based on the measures results, an average photoelectric conversion efficiency and an uniformity of photoelectric conversion efficiency were evaluated in each case. The evaluated results are collectively shown in Table 2.

3. For each of the solar cell modules of Examples 1-1 to 1-4 and Comparative Examples 1-1 to 1-4, the initial photoelectric conversion efficiency thereof was measured by means of the above-described solar simulator. Then, the solar cell module was positioned in a dark atmosphere with temperature of 85° C. and humidity of 85% and maintained for 500 hours while applying a reverse bias of 10 V.

Thereafter, the photoelectric conversion efficiency of the solar cell module was measured by means of the solar simulator. Then, for each solar cell module, a change rate between the initial photoelectric conversion efficiency and the photoelectric conversion efficiency after the endurance was examined. The examined results are collectively shown in Table 2.

As the results shown in Table 2 illustrate, it is understood that the products of Examples 1-1 to 1-4 are superior to those of Comparative Examples 1-1 to 1-4. This indicates that the deposited film-forming process of the present invention is excellent.

### Example 2

### Examples 2-1 to 2-4

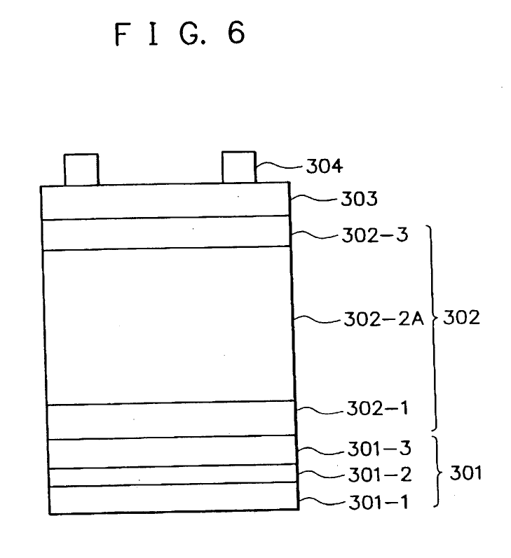

Following the procedures of Example 1 using the deposited film-forming apparatus shown in FIG. 2 except for changing the film-forming conditions to those shown in Table 3, there was prepared a photovoltaic element having such configuration as shown in FIG. 6 which contains a deposited film formed according to the present invention.

FIG. 6 is a schematic cross-sectional view illustrating an example of a photovoltaic element containing a silicon series deposited film formed according to the present invention, which is prepared in this example.

The constitution of the photovoltaic element shown in FIG. 6 is the same as that of the photovoltaic element shown in FIG. 3 except for the point that the i-type crystalline phase-containing semiconductor layer 302 in FIG. 3 is changed to an i-type amorphous semiconductor layer 302-2A, that is, the semiconductor layer 302 in FIG. 6 comprises an n-type amorphous semiconductor layer 302-1. an i-type amorphous semiconductor layer 302-2A, and a p-type crystalline phase-containing semiconductor layer 302-3.

Using the deposited film-forming apparatus 201 shown in FIG. 2, this photovoltaic element was prepared by repeating the procedures adopted for the preparation of the photovoltaic element in Example 1, except for changing the film-forming conditions to those shown in Table 3. Particularly, on a stainless steel web substrate 204 which is the same as that used in Example 1, there were sequentially and continuously formed an n-type amorphous semiconductor layer 302-1 having a thickness of 30 nm in the film-forming vacuum vessel 211, an i-type amorphous semiconductor layer 302-2A having a thickness of 300 nm in the film-forming vacuum vessel 212, and a p-type crystalline phase-containing semiconductor layer 302-3 having a thickness of 10 nm in the film-forming vacuum vessel 213 to form a p-i-n single cell semiconductor layer 302 on the web substrate 204.

Here, in the deposition chamber of the film-forming vacuum vessel 211, a high frequency power whose frequency is 13.56 MHz and having a power density of 5 mW/cm³ was introduced from the power application electrode 241 (comprising a metal electrode made of aluminum). Similarly, in the deposition chamber of the film-forming vacuum vessel 213, a high frequency power whose frequency is 13.56 MHz and having a power density of 30 mW/cm³ was introduced from the power application electrode 243 (comprising a metal electrode made of aluminum). And in the deposition chamber of the film-forming vacuum vessel 212, a high frequency power whose frequency is 60 MHz and having a power density of 80 mW/cm³ was introduced from the power application electrode 242 (comprising a metal electrode made of aluminum). Simultaneously with this, a direct current potential from the direct current power source 257 was overlapped to the high frequency power, particularly as shown in Table 4, this operation to overlap the direct current potential to the high frequency power was conducted separately for four cases (Examples 2-1 to 2-4), specifically by changing the direct current potential of the power application electrode 242 to −50 V, −100 V, −200 V, and −300 V against the earth potential.

In this way, there were prepared a web-shaped photovoltaic element of Example 2-1, a web-shaped photovoltaic element of Example 2-2, a web-shaped photovoltaic element of Example 2-3, and a web-shaped photovoltaic element of Example 2-4. Each of these web-shaped photovoltaic elements was cut and processed by using a continuous module-making apparatus, to obtain a plurality of solar cell modules having a size of 36 cm×22 cm.

### Comparative Example 2

### Comparative Examples 2-1 to 2-4

The procedures of Example 2 were repeated except for using a high frequency plasma CVD apparatus 201-A shown in FIG. 4 whose constitution is the same as that of high frequency plasma CVD apparatus 201 shown in FIG. 2 except for not having the arc discharge-detecting detector 258, wherein in the film-forming vacuum vessel 212, as well as in Example 2, as shown in Table 4, the operation to overlap the direct current potential to the high frequency power was conducted separately for four cases (Comparative Examples 2-1 to 2-4), specifically by changing the direct current potential of the power application electrode 242 to −50 V, −100 V, −200 V. and −300 V (Comparative Examples 1-1 to 1-4) against the earth potential. In this way, there were prepared a web-shaped photovoltaic element of Comparative Example 2-1, a web-shaped photovoltaic element of Comparative Example 2-2, a web-shaped photovoltaic element of Comparative Example 2-3, and a web-shaped photovoltaic element of Comparative Example 2-4.

The state of the plasma in the 212 in Example 2 (that is, Examples 2-1 to 2-4) was stable. On the other hand, for the state of the plasma in the deposition chamber of the film-forming vacuum vessel 212 in Comparative Example 2 (that is, Comparative Examples 2-1 to 2-4), it was observed that as the direct current potential of the power application electrode 242 was made to be smaller, namely, as the direct current voltage component to be overlapped was increased, the spark occurring frequency was increased.

Each of the web-shaped photovoltaic elements obtained in the above was cut and processed by using the continuous module-making apparatus, to obtain a plurality of solar cell modules having a size of 36 cm×22 cm.

### Evaluation

1. Each of the solar cell modules of Examples 2-1 to 2-4 and Comparative Examples 2-1 to 2-4 was evaluated with respect to the adhesion of the semiconductor layer with the substrate in accordance with the lattice pattern tape method prescribed in JIS standard-K5400 8.5.1(cut clearance interval: 1 mm; number of lattices: 100). The evaluated results are collectively shown in Table 4.

2. On the surface of the semiconductor layer of each of the web-shaped photovoltaic elements of Examples 2-1 to 2-4 and Comparative Examples 2-1 to 2-4, 100 transparent electrodes (comprising a transparent and electrically conductive layer) having a size of 1 cm×1 cm were spacedly formed at an equal interval, followed by forming a collecting electrode on each transparent electrode, to form 100 subcells spacedly arranged. For each of the 100 subcells thus formed in each case, the photoelectric conversion efficiency thereof was measured by using a solar simulator (AM 1.5, 100 mW/cm²). Based on the measures results, an average photoelectric conversion efficiency and an uniformity of photoelectric conversion efficiency were evaluated in each case. The evaluated results are collectively shown in Table 4.

3. For each of the solar cell modules of Examples 2-1 to 2-4 and Comparative Examples 2-1 to 2-4, the initial photoelectric conversion efficiency thereof was measured by means of the above-described solar simulator. Then, the solar cell module was positioned in a dark atmosphere with temperature of 85° C. and humidity of 85% and maintained for 500 hours while applying a reverse bias of 10 V.

Thereafter, the photoelectric conversion efficiency of the solar cell module was measured by means of the solar simulator. Then, for each solar cell module, a change rate between the initial photoelectric conversion efficiency and the photoelectric conversion efficiency after the endurance was examined. The examined results are collectively shown in Table 4.

As the results shown in Table 4 illustrate, it is understood that the products of Examples 2-1 to 2-4 are superior to those of Comparative Examples 2-1 to 2-4. This indicates that the deposited film-forming process of the present invention is excellent.

As described in the above, it is understood that the deposited film-forming apparatus and the deposited film-forming process in the first aspect of the present invention enable to introduce a large high frequency power to efficiently form a high quality deposited film having an excellent uniformity at a high deposition rate.

### EXAMPLES OF THE SECOND ASPECT

### Example 3

### Examples 3-1 to 3-4

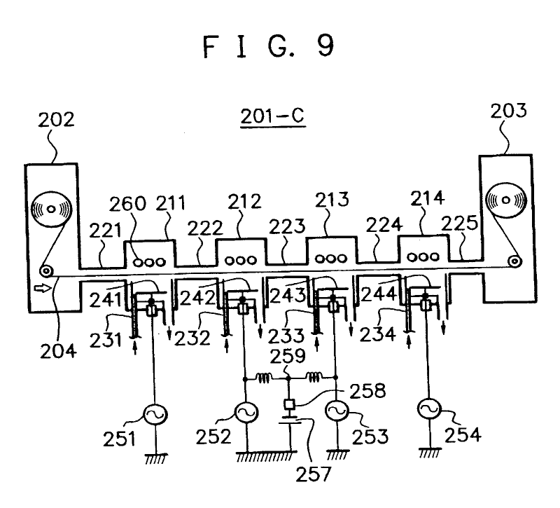

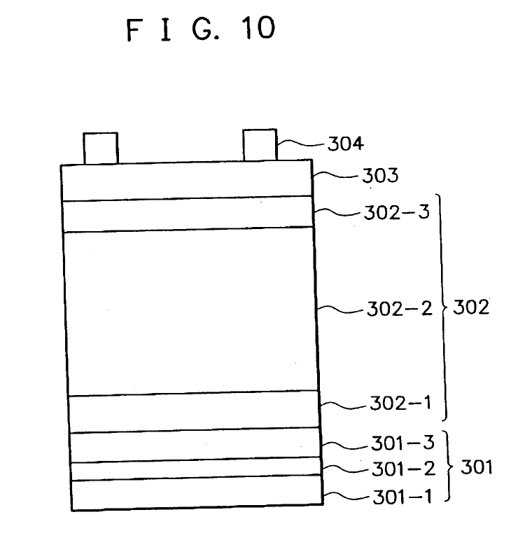

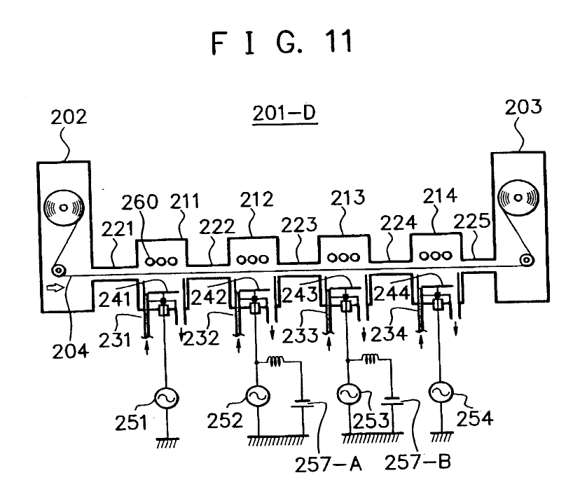

In this example, a photovoltaic element having such configuration as shown in FIG. 10 was prepared by forming deposited films using a deposited film-forming apparatus 201-C shown in FIG. 9 of the present invention.

FIG. 9 is a schematic diagram illustrating a high frequency plasma CVD apparatus of the roll-to-roll system, as an example of the deposited film-forming apparatus in the second aspect of the present invention.

The high frequency plasma CVD apparatus 201-C shown in FIG. 9 comprises a substrate delivery vacuum vessel 202, film-forming vacuum vessels 211-214, and a substrate take-up vacuum vessel 203 which are communicated with each other through gas gates 221-225. A pay-out bobbin having a web substrate 204 wound thereon is positioned in the substrate delivery vacuum vessel 202. The web substrate 204 is paid out from the pay-out bobbin and delivered from the substrate delivery vacuum vessel 202, followed by passing through the gas gate 221, the film-forming vacuum vessel 211, the gas gate 222, the film-forming vacuum vessel 212, the gas gate 223, the film-forming vacuum vessel 213, the gas gate 224, the film-forming vacuum vessel 214 and the gas gate 225 to enter the substrate take-up vacuum vessel 203 where the beginning portion of the web substrate 204 is fixed to and wound a take-up bobbin positioned in the substrate take-up vacuum vessel 203. In the film-forming operation, the web substrate 204 is moved from the substrate delivery vacuum vessel 202 to the substrate take-up vacuum vessel 203 where the web substrate 204 is wound on the take-up bobbin In the substrate take-up vacuum vessel 203.

The film-forming vacuum vessels 211-214 have respectively a deposition chamber having a plasma generation region. Each deposition chamber is structured to have a discharge space in which a plasma is generated, whose top is defined by the substrate 204, whose bottom is defined by a plate-shaped power application electrode (241, 242, 243, 244) and whose circumference is circumscribed by a discharge plate arranged so as to surround the power application electrode.

Each of film-forming vacuum vessels 211-214 is provided with a gas introduction pipe (231, 232, 233, 234) for introducing dilution gas or/and raw material gas and is also provided with an exhaust pipe connected to a vacuum pump (not shown). In each of film-forming vacuum vessels 211-214, there is provided a lamp heater 260 for heating the substrate 204.

By applying a high frequency power from a high frequency power source (251, 252, 253, 254) to the plate-shaped power application electrode (241, 242, 243, 244) in the deposition chamber of the film-forming vacuum vessel (211, 212, 213, 214) to generate glow discharge, whereby raw material gas introduced through the gas introduction pipe (231, 232, 233, 234) is decomposed to form a deposited film as a semiconductor layer on the substrate 204.

The power application electrode (241, 242, 243, 244) is opposed to the substrate 204, where a height-adjusting mechanism (not shown) is provided. By this height-adjusting mechanism, it is possible to change the distance between the substrate 204 and the power application electrode (241, 242, 243) and at the same time, it is possible to change the volume of the discharge space.

In each of the film-forming vacuum vessels 212 and 213 containing the factors of the present invention, the high frequency power source (252, 253) is connected to the power application electrode (242, 243) through a matching box (not shown). A direct current power source 257 is connected to the pathway between the high frequency power source 252 and the power application electrode 242 and to the pathway between the high frequency power source 253 and the power application electrode 243, respectively through a choke coil. Particularly, the direct current power source 257 is connected with both the power application electrode 242 and the power application electrode 243 through a brunch point 259.

An arc discharge-detecting detector 258 (including an arc discharge preventive means) is provided on the pathway between the direct current power source 257 and the brunch point 259. Specifically, the arc discharge preventive means provided in the arc discharge-detecting detector 258 is connected between the direct current power source 257 and the brunch point 259 such that it is connected with the direct current power source 257 in series connection and is connected with each of the high frequency power sources 252 and 253 in parallel connection.

The arc discharge-detecting detector 258 functions to detect a symptom of occurrence of arc discharge. When a symptom of occurrence of arc discharge is detected by the arc discharge-detecting detector 258, the arc discharge preventive means is actuated to prevent the occurrence of arc discharge.

FIG. 10 is a schematic cross-sectional view illustrating an example of a photovoltaic element containing a deposited film formed according to the present invention, which is prepared in this example.

In FIG. 10, reference numeral 301 indicates a substrate, reference numeral 302 a semiconductor layer, reference numeral 303 a transparent and electrically conductive layer, and reference numeral 304 a collecting electrode. The substrate 301 comprises a base member 301-1, a metal layer 301-2, and a first transparent and electrically conductive layer 301-3. The semiconductor layer 302 comprises an n-type amorphous semiconductor layer 302-1. an i-type crystalline phase-containing semiconductor layer 302-2, and a p-type crystalline phase-containing semiconductor layer 302-3. Thus, the photovoltaic element shown in FIG. 10 is a so-called p-i-n type single cell photovoltaic element.

There was prepared a p-i-n type single cell photovoltaic element shown in FIG. 10 in the following manner, using the apparatus shown in FIG. 9.

1. Provision of Web Substrate:

As the web substrate 204, there was provided a substrate roll comprising a well-cleaned web substrate made of stainless steel (SUS430BA) (having a thickness of 0.125 mm, a width of 50 cm and a length of 200 m) having a 100 nm thick Ag thin film (as a metal layer 301-2) and a 1.2 μm thick ZnO thin film (as a first transparent and electrically conductive layer 301-3) formed in this order thereon by means of a conventional roll-to-roll type sputtering apparatus (not shown) which is wound on a pay-out bobbin.

2. Preparation of Photovoltaic Element:

The pay-out bobbin having the web substrate 204 wound thereon was positioned in the substrate delivery vacuum vessel 202 of the apparatus shown in FIG. 9. From the pay-out bobbin, the web substrate 204 was paid out and delivered from the substrate delivery vacuum vessel 202, followed by passing through the gas gate 221, the film-forming vacuum vessel 211, the gas gate 222, the film-forming vacuum vessel 212, the gas gate 223, the film-forming vacuum vessel 213, the gas gate 224, the film-forming vacuum vessel 214 and the gas gate 225 to enter the substrate take-up vacuum vessel where the beginning portion of the web substrate 204 was fixed and wound on the substrate take-up bobbin, where the web substrate 204 was made to have earth potential. And the transportation system of the web substrate 204 was adjusted so that the web substrate could be continuously and smoothly transported from the substrate delivery vacuum vessel 202 to the take-up vacuum vessel 203 without being distorted or warped.

Then, each of the substrate delivery vacuum vessel 202, the film-forming vacuum vessels 212-214, and the take-up vacuum vessel 203 was evacuated until the inner pressure reached about 1.0 mPa by means of the exhaustion system comprising the vacuum pump (not shown).

While continuing this evacuation, raw material gas and dilution gas were introduced into the film-forming vacuum vessels 211, 212, 213 and 214 through the gas introduction pipes 231, 232, 233 and 234, simultaneously with this, H₂ gas as a gate gas was flown into the gas gates 221, 222, 223, 224 and 225 at a flow rate of 500 cm³/min (normal). While maintaining this state, the exhausting performance of each exhaustion system was controlled to adjust the gas pressure in each of the film-forming vacuum vessels 211, 212, 213 and 214 to have a prescribed value. The film-forming conditions in each of the film-forming vacuum vessels 211, 212, 213 and 214 are shown in Table 5.

When the gas pressure in each of the film-forming vacuum vessels 211, 212, 213 and 214 became stable at the prescribed value, the web substrate 204 was started moving at a prescribed transportation speed from the substrate delivery vacuum vessel 202 toward the substrate take-up vacuum vessel 203.

Then, a high frequency power from each of the high frequency power sources 251, 252, 253 and 254 was applied to each of the power application electrodes 241, 242, 243 and 244 in each of the film-forming vacuum vessels 211, 212, 213 and 214 to generate glow discharge in the deposition chamber in each of the film-forming vacuum vessels 211, 212, 213 and 214 whereby sequentially and continuously forming an n-type amorphous semiconductor layer 302-1 having a thickness of 30 nm in the film-forming vacuum vessel 211, an i-type crystalline phase-containing semiconductor layer 302-2 having a thickness of 1.5 μm in the film-forming vacuum vessels 212 and 213, and a p-type crystalline phase-containing semiconductor layer 302-3 having a thickness of 10 nm in the film-forming vacuum vessel 214 to form a p-i-n single cell semiconductor layer 302 on the web substrate 204. Thus, there was obtained a photovoltaic element in a web form.

Here, in the deposition chamber of the film-forming vacuum vessel 211, a high frequency power whose frequency is 13.56 MHz and having a power density of 5 mW/cm³ was introduced from the power application electrode 241 (comprising a metal electrode made of aluminum). Similarly, in the deposition chamber of the film-forming vacuum vessel 214, a high frequency power whose frequency is 13.56 MHz and having a power density of 30 mW/cm³ was introduced from the power application electrode 244 (comprising a metal electrode made of aluminum). And in the deposition chamber of the film-forming vacuum vessel 212 and the deposition chamber of the film-forming vacuum vessel 213, a high frequency power whose frequency is 60 MHz and having a power density of 400 mW/cm³ was introduced from the power application electrode 242 (comprising a metal electrode made of aluminum) and the power application electrode 243 (comprising a metal electrode made of aluminum). Simultaneously with this, in the deposition chamber of the film-forming vacuum vessel 212 and the deposition chamber of the film-forming vacuum vessel 213, a direct current potential from the direct current power source 257 was overlapped to the high frequency power. As shown in Table 6, this operation to overlap the direct current potential to the high frequency power was conducted separately for four cases (Examples 3-1 to 3-4), specifically by changing the direct current potential of each of the power application electrode 242 and 243 to −50 V, −100 V, −200 V, and −300 V against the earth potential.

In this way, there were prepared a web-shaped photovoltaic element of Example 3-1, a web-shaped photovoltaic element of Example 3-2, a web-shaped photovoltaic element of Example 3-3, and a web-shaped photovoltaic element of Example 3-4. Each of these web-shaped photovoltaic elements was cut and processed by using a continuous module-making apparatus, to obtain a plurality of solar cell modules having a size of 36 cm×22 cm.

### Comparative Example 3

### Comparative Examples 3-1 to 3-4

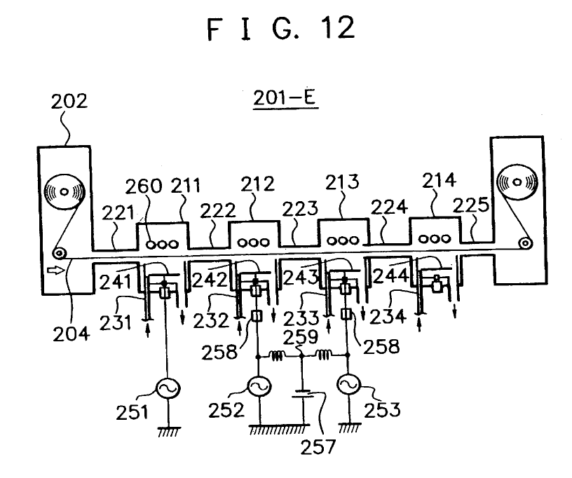

The procedures of Example 3 were repeated except for using a high frequency plasma CVD apparatus 201-D shown in FIG. 11 whose constitution is the same as that of high frequency plasma CVD apparatus 201 shown in FIG. 9 except that the arc discharge-detecting detector 258 is not provided and instead of the direct current power source 257, direct current power sources 257-A and 257-B are separately connected with the power application electrode 242 and the power application electrode 243, wherein in the film-forming vacuum vessel 212 and the film-forming vacuum vessel 213, as well as in Example 3, as shown in Table 6, the operation to overlap the direct current potential to the high frequency power was conducted for four cases (Comparative Examples 3-1 to 3-4), specifically by changing the direct current potential of each of the power application electrodes 242 and 243 to −50 V, −100 V, −200 V, and −300 V against the earth potential.

In this way, there were prepared a web-shaped photovoltaic element of Comparative Example 3-1, a web-shaped photovoltaic element of Comparative Example 3-2, a web-shaped photovoltaic element of Comparative Example 3-3, and a web-shaped photovoltaic element of Comparative Example 3-4.

The state of the plasma in the deposition chamber of each of the film-forming vacuum vessels 212 and 213 in Example 3 (that is, Examples 3-1 to 3-4) was stable. On the other hand, for the state of the plasma in the deposition chamber of each of the film-forming vacuum vessels 212 and 213 in Comparative Example 3 (that is, Comparative Examples 3-1 to 3-4), it was observed that as the direct current potential of each of the power application electrodes 242 and 243 was made to be smaller, namely, as the direct current voltage component to be overlapped was increased, the spark occurring frequency was increased.

Each of the web-shaped photovoltaic elements obtained in the above was cut and processed by using the continuous module-making apparatus, to obtain a plurality of solar cell modules having a size of 36 cm×22 cm.

### Comparative Example 3-5

Using a high frequency plasma CVD apparatus 201-E shown in FIG. 12 whose constitution is the same as that of high frequency plasma CVD apparatus 201-C shown in FIG. 9 except that two arc discharge-detecting detectors 258 are provided such that one is connected with the direct current power source 257 in series connection and is connected with the high frequency power source 252 in series connection and the other is connected with the direct current power source 257 in series connection and is connected with the high frequency power source 253 in series connection, the formation of a p-i-n single cell semiconductor layer 302 on the web substrate 204 was tried in the same manner as in Example 3. However, in each of the film-forming vacuum vessels 212 and 213, the arc discharge preventive means was actuated quite frequently to disconnect the electric connection between the power application electrode and the high frequency power source and to quite frequently cut off the high frequency power, where the plasma could not be stably maintained.

### Evaluation

1. Each of the solar cell modules of Examples 3-1 to 3-4 and Comparative Examples 3-1 to 3-4 was evaluated with respect to the adhesion of the semiconductor layer with the substrate in accordance with the lattice pattern tape method prescribed in JIS standard-K5400 8.5.1(cut clearance interval: 1 mm; number of lattices: 100). The evaluated results are collectively shown in Table 6.

2. On the surface of the semiconductor layer of each of the web-shaped photovoltaic elements of Examples 3-1 to 3-4 and Comparative Examples 3-1 to 3-4, 100 transparent electrodes (comprising a transparent and electrically conductive layer) having a size of 1 cm×1 cm were spacedly formed at an equal interval, followed by forming a collecting electrode on each transparent electrode, to form 100 subcells spacedly arranged. For each of the 100 subcells thus formed in each case, the photoelectric conversion efficiency thereof was measured by using a solar simulator (AM 1.5, 100 mW/cm²). Based on the measures results, an average photoelectric conversion efficiency and an uniformity of photoelectric conversion efficiency were evaluated in each case. The evaluated results are collectively shown in Table 6.

3. For each of the solar cell modules of Examples 3-1 to 3-4 and Comparative Examples 3-1 to 3-4, the initial photoelectric conversion efficiency thereof was measured by means of the above-described solar simulator. Then, the solar cell module was positioned in a dark atmosphere with temperature of 85° C. and humidity of 85% and maintained for 500 hours while applying a reverse bias of 10 V.

Thereafter, the photoelectric conversion efficiency of the solar cell module was measured by means of the solar simulator. Then, for each solar cell module, a change rate between the initial photoelectric conversion efficiency and the photoelectric conversion efficiency after the endurance was examined. The examined results are collectively shown in Table 6.

As the results shown in Table 6 illustrate, it is understood that the products of Examples 3-1 to 3-4 are superior to those of Comparative Examples 3-1 to 3-4. This indicates that the deposited film-forming process of the present invention is excellent.

### Example 4

### Examples 4-1 to 4-4

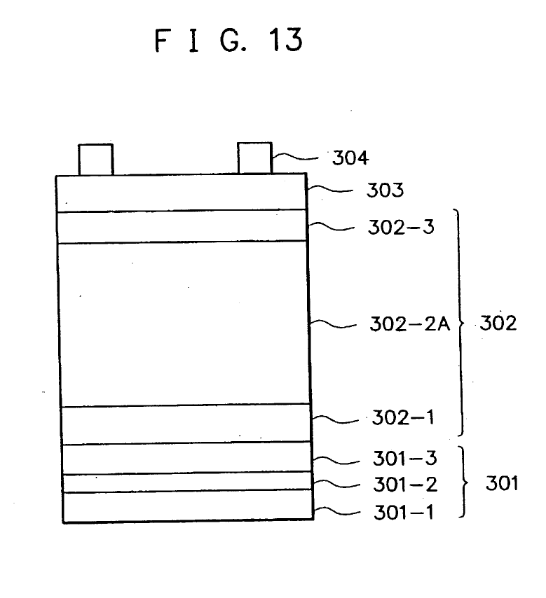

Following the procedures of Example 3 using the deposited film-forming apparatus 201-C shown in FIG. 9 except for changing the film-forming conditions to those shown in Table 7, there was prepared a photovoltaic element having such configuration as shown in FIG. 13 which contains a deposited film formed according to the present invention.

FIG. 13 is a schematic cross-sectional view illustrating an example of a photovoltaic element containing a silicon series deposited film formed according to the present invention, which is prepared in this example.

The constitution of the photovoltaic element shown in FIG. 13 is the same as that of the photovoltaic element shown in FIG. 10 except for the point that the i-type crystalline phase-containing semiconductor layer 302 in FIG. 10 is changed to an i-type amorphous semiconductor layer 302-2A, that is, the semiconductor layer 302 in FIG. 13 comprises an n-type amorphous semiconductor layer 302-1, an i-type amorphous semiconductor layer 302-2A, and a p-type crystalline phase-containing semiconductor layer 302-3.

Using the deposited film-forming apparatus 201-C shown in FIG. 9, this photovoltaic element was prepared by repeating the procedures adopted for the preparation of the photovoltaic element in Example 3, except for changing the film-forming conditions to those shown in Table 7. Particularly, on a stainless steel web substrate 204 which is the same as that used in Example 3, there were sequentially and continuously formed an n-type amorphous semiconductor layer 302-1 having a thickness of 30 nm in the film-forming vacuum vessel 211, an i-type amorphous semiconductor layer 302-2A having a thickness of 300 nm in the film-forming vacuum vessels 212 and 213, and a p-type crystalline phase-containing semiconductor layer 302-3 having a thickness of 10 nm in the film-forming vacuum vessel 214 to form a p-i-n single cell semiconductor layer 302 on the web substrate 204.

Here, in the deposition chamber of the film-forming vacuum vessel 211, a high frequency power whose frequency is 13.56 MHz and having a power density of 5 mW/cm³ was introduced from the power application electrode 241 (comprising a metal electrode made of aluminum). Similarly, in the deposition chamber of the film-forming vacuum vessel 214, a high frequency power whose frequency is 13.56 MHz and having a power density of 30 mW/cm³ was introduced from the power application electrode 244 (comprising a metal electrode made of aluminum). And in the deposition chamber of each of the film-forming vacuum vessels 212 and 213, a high frequency power whose frequency is 60 MHz and having a power density of 80 mW/cm³ was introduced from each of the power application electrodes 242 and 243 (comprising a metal electrode made of aluminum). Simultaneously with this, a direct current potential from the direct current power source 257 was overlapped to the high frequency power in the deposition chamber of each of the film-forming vacuum vessels 212 and 213, particularly as shown in Table 8, the operation to overlap the direct current to the high frequency power was conducted for four cases (Examples 4-1 to 4-4), specifically by changing the direct current potential of the power application electrode 242 to −50 V, −100 V, −200 V, and −300 V against the earth potential.

In this way, there were prepared a web-shaped photovoltaic element of Example 4-1, a web-shaped photovoltaic element of Example 4-2, a web-shaped photovoltaic element of Example 4-3, and a web-shaped photovoltaic element of Example 4-4. Bach of these web-shaped photovoltaic elements was cut and processed by using a continuous module-making apparatus, to obtain a plurality of solar cell modules having a size of 36 cm×22 cm.

### Comparative Example 4

### Comparative Examples 4-1 to 4-4

The procedures of Example 4 were repeated except for using a high frequency plasma CVD apparatus 201-D shown in FIG. 11 whose constitution is the same as that of high frequency plasma CVD apparatus 201 shown in FIG. 9 except that the arc discharge-detecting detector 258 is not provided and two direct current power sources 257-A and 257-B are provided such that they are separately connected with the power application electrode 242 and the power application electrode 243, wherein in the each of the film-forming vacuum vessels 212 and 213, as well as in Example 4, as shown in Table 8, the operation to overlap the direct current potential to the high frequency power was conducted separately for four cases (Comparative Examples 4-1 to 4-4), specifically by changing the direct current potential of each of the power application electrodes 242 and 243 to −50 V, −100 V, −200 V, and −300 V against the earth potential. In this way, there were prepared a web-shaped photovoltaic element of Comparative Example 4-1, a web-shaped photovoltaic element of Comparative Example 4-2, a web-shaped photovoltaic element of Comparative Example 4-3, and a web-shaped photovoltaic element of Comparative Example 4-4.

The state of the plasma in the deposition chamber of each of the film-forming vacuum vessels 212 and 213 in Example 4 (that is, Examples 4-1 to 4-4) was stable. On the other hand, for the state of the plasma in the deposition chamber of each of the film-forming vacuum vessels 212 and 213 in Comparative Example 4 (that is, Comparative Examples 4-1 to 4-4), it was observed that as the direct current potential of the power application electrode was made to be smaller, namely, as the direct current voltage component to be overlapped was increased, the spark occurring frequency was increased.

Each of the web-shaped photovoltaic elements obtained in the above was cut and processed by using the continuous module-making apparatus, to obtain a plurality of solar cell modules having a size of 36 cm×22 cm.

### Evaluation

1. Each of the solar cell modules of Examples 4-1 to 4-4 and Comparative Examples 4-1 to 4-4 was evaluated with respect to the adhesion of the semiconductor layer with the substrate in accordance with the lattice pattern tape method prescribed in JIS standard-K5400 8.5.1(cut clearance interval: 1 mm; number of lattices: 100). The evaluated results are collectively shown in Table 8.

2. On the surface of the semiconductor layer of each of the web-shaped photovoltaic elements of Examples 4-1 to 4-4 and Comparative Examples 4-1 to 4-4, 100 transparent electrodes (comprising a transparent and electrically conductive layer) having a size of 1 cm×1 cm were spacedly formed at an equal interval, followed by forming a collecting electrode on each transparent electrode, to form 100 subcells spacedly arranged. For each of the 100 subcells thus formed in each case, the photoelectric conversion efficiency thereof was measured by using a solar simulator (AM 1.5, 100 mW/cm²). Based on the measures results, an average photoelectric conversion efficiency and an uniformity of photoelectric conversion efficiency were evaluated in each case. The evaluated results are collectively shown in Table 8.

3. For each of the solar cell modules of Examples 4-1 to 4-4 and Comparative Examples 4-1 to 4-4, the initial photoelectric conversion efficiency thereof was measured by means of the above-described solar simulator. Then, the solar cell module was positioned in a dark atmosphere with temperature of 85° C. and humidity of 85% and maintained for 500 hours while applying a reverse bias of 10 V. Thereafter, the photoelectric conversion efficiency of the solar cell module was measured by means of the solar simulator. Then, for each solar cell module, a change rate between the initial photoelectric conversion efficiency and the photoelectric conversion efficiency after the endurance was examined. The examined results are collectively shown in Table 8.

As the results shown in Table 8 illustrate, it is understood that the products of Examples 4-1 to 4-4 are superior to those of Comparative Examples 4-1 to 4-4. This indicates that the deposited film-forming process of the present invention is excellent.

As described in the above, it is understood that the deposited film-forming apparatus and the deposited film-forming process in the second aspect of the present invention enable to introduce a large high frequency power to efficiently form a high quality deposited film having an excellent uniformity at a high deposition rate. And this can be achieved by a deposited film-forming apparatus whose components are diminished as described in the embodiments of the second aspect of the present invention. Further, according to the second aspect of the present invention, it is not necessary that an arc discharge-detecting detector is used in number to correspond the number of the power application electrodes. This makes it possible to more downsize the scale of the apparatus in comparison with the case where an arc discharge-detecting detector is provided for every power application electrode.

TABLE 1

| | | |
|---|---|---|
| film-forming con- | raw material gas | SiH₄: 20 cm³/min |
| ditions in the vacuum | | (normal) |
| vessel 211 | | H₂: 100 cm³/min(normal) |
| | | PH₃(diluted by H₂ to |
| | | 2%): 30 cm³/min |
| | | (normal) |
| | substrate temperature | 300° C. |
| | gas pressure | 100 Pa |
| film-forming con- | raw material gas | SiH₄: 30 cm³/min |
| ditions in the vacuum | | (normal) |
| vessel 212 | | SiF₄: 50 cm³/min |
| | | (normal) |
| | | H₂: 200 cm³/min(normal) |
| | substrate temperature | 300° C. |
| | gas pressure | 100 Pa |
| film-forming con- | raw material gas | SiH₄: 10 cm³/min |
| ditions in the vacuum | | (normal) |
| vessel 213 | | H₂: 800 cm³/min(normal) |
| | | BF₃(diluted by H₂ to |
| | | 2%): 100 cm³/min |
| | | (normal) |
| | substrate temperature | 200° C. |
| | gas pressure | 150 Pa |

TABLE 2

| | direct current | | average value of | uniformity of | change in the photoelectric |
|---|---|---|---|---|---|
| | potential of the | lattice | photoelectric | photoelectric | conversion efficiency by the high |
| | power application | pattern tape | conversion | conversion | temperature-high humidity |
| | electrode ※1 | method ※2 | efficiency ※3 | efficiency ※4 | reverse bias application test ※5 |
| Example 1-1 | −50 V | 1 | 1 | 1 | 0.98 |
| Example 1-2 | −100 V | 1.0 | 1.04 | 0.98 | 0.99 |
| Example 1-3 | −200 V | 1.0 | 1.07 | 1.01 | 0.98 |
| Example 1-4 | −300 V | 1.0 | 1.06 | 1.02 | 0.98 |
| Comparative | −50 V | 1.0 | 0.98 | 1.07 | 0.96 |
| Example 1-1 | | | | | |
| Comparative | −100 V | 0.98 | 0.94 | 1.12 | 0.94 |
| Example 1-2 | | | | | |
| Comparative | −200 V | 0.95 | 0.91 | 1.15 | 0.92 |
| Example 1-3 | | | | | |
| Comparative | −300 V | 0.87 | 0.88 | 1.2 | 0.91 |
| Example 1-4 | | | | | |

※1: value obtained when the number of the lattices not peeled in Example 1-1 is normalized at 1.
※2: value obtained when the value of the photoelectric conversion efficiency of Example 1-1 is normalized at 1.
※3: value obtained when the value of the standard deviation of Example 1-1 is normalized at 1.
※4: value of the photoelectric conversion efficiency after the test/ the initial photoelectric conversion efficiency.

TABLE 3

| | | |
|---|---|---|
| film-forming conditions | raw material gas | SiH₄: 20 cm³/min(normal) |
| in the vacuum vessel 211 | | H₂: 100 cm³/min(normal) |
| | | PH₃(diluted by H₂ to |
| | | 2%): 50 cm³/min(normal) |
| | substrate | 300° C. |
| | temperature | |
| | gas pressure | 100 Pa |
| film-forming conditions | raw material gas | SiH_{4: 200 cm}³/min(normal) |
| in the vacuum vessel 212 | | H₂: 3000 cm³/min(normal) |
| | substrate | 300° C. |
| | temeperature | |
| | gas pressure | 300 Pa |
| film-forming conditions | raw material gas | SiH₄: 10 cm³/min(normal) |
| in the vacuum vessel 213 | | H₂: 800 cm³/min(normal) |
| | | BF₃(diluted by H₂ to |
| | | 2%): 100 cm³/min(normal) |
| | substrate | 200° C. |
| | temperature | |
| | gas pressure | 150 Pa |

TABLE 4

| | direct current | | average value of | uniformity of | change in the photoelectric |
|---|---|---|---|---|---|
| | potential of the | lattice | photoelectric | photoelectric | conversion efficiency by the high |
| | power application | pattern tape | conversion | conversion | temperature-high humidity |
| | electrode ※1 | method ※2 | efficiency ※3 | efficiency ※4 | reverse bias application test ※5 |
| Example 2-1 | −50 V | 1 | 1 | 1 | 0.98 |
| Example 2-2 | −100 V | 1.0 | 1.02 | 1.02 | 0.98 |
| Example 2-3 | −200 V | 1.0 | 1.04 | 1.00 | 0.98 |
| Example 2-4 | −300 V | 1.0 | 1.04 | 1.02 | 0.98 |
| Comparative | −50 V | 1.0 | 0.98 | 1.06 | 0.98 |
| Example 2-1 | | | | | |
| Comparative | −100 V | 0.98 | 0.96 | 1.10 | 0.96 |
| Example 2-2 | | | | | |
| Comparative | −200 V | 0.97 | 0.96 | 1.10 | 0.94 |
| Example 2-3 | | | | | |
| Comparative | −300 V | 0.94 | 0.94 | 1.14 | 0.94 |
| Example 2-4 | | | | | |

※1: value obtained when the number of the lattices not peeled in Example 1-1 is normalized at 1.
※2: value obtained when the value of the photoelectric conversion efficiency of Example 1-1 is normalized at 1.
※3: value obtained when the value of the standard deviation of Example 1-1 is normalized at 1.
※4: value of the photoelectric conversion efficiency after the test/ the initial photoelectric conversion efficiency.

TABLE 5

| | | |
|---|---|---|
| film-forming conditions | raw material gas | SiH₄: 20 cm³/min(normal) |
| in the vacuum vessel 211 | | H₂: 100 cm³:min(normal) |
| | | PH₃(diluted by H₂to 2%): |
| | | 30 cm³/min(normal) |
| | substrate | 300° C. |
| | temperature | |
| | gas pressure | 100 Pa |
| film-forming conditions | raw material gas | SiH₄: 30 cm³/min(normal) |
| in the vacuum vessel 212 | | SiF₄: 60 cm³/min(normal) |
| | | H₂: 250 cm³/min(normal) |
| | substrate | 300° C. |
| | temperature | |
| | gas pressure | 100 Pa |
| | | SiH₄: 10 cm³/min(normal) |
| film-forming conditions | raw material gas | H₂: 800 cm³/min(normal) |
| in the vacuum vessel 212 | | BF₃(diluted by H₂ to |
| | | 2%) 100 cm³/min(normal) |
| | substrate | 200° C. |
| | temperature | |
| | gas pressure | 100 Pa |

TABLE 6

| | direct current | | average value of | uniformity of | change in the photoelectric |
|---|---|---|---|---|---|
| | potential of the | lattice | photoelectric | photoelectric | conversion efficiency by the high |
| | power application | pattern tape | conversion | conversion | temperature-high humidity |
| | electrode ※1 | method ※2 | efficiency ※3 | efficiency ※4 | reverse bias application test ※5 |
| Example 3-1 | −50 V | 1 | 1 | 1 | 0.98 |
| Example 3-2 | −100 V | 1.0 | 1.03 | 0.98 | 0.99 |
| Example 3-3 | −200 V | 1.0 | 1.06 | 1.01 | 0.98 |
| Example 3-4 | −300 V | 1.0 | 1.08 | 1.02 | 0.98 |
| Comparative | −50 V | 1.0 | 0.98 | 1.05 | 0.96 |
| Example 3-1 | | | | | |
| Comparative | −100 V | 0.98 | 0.96 | 1.10 | 0.96 |
| Example 3-2 | | | | | |
| Comparative | −200 V | 0.97 | 0.94 | 1.12 | 0.94 |
| Example 3-3 | | | | | |
| Comparative | −300 V | 0.93 | 0.90 | 1.15 | 0.92 |
| Example 3-4 | | | | | |

※1: value obtained when the number of the lattices not peeled in Example 1-1 is normalized at 1.
※2: value obtained when the value of the photoelectric conversion efficiency of Example 1-1 is normalized at 1.
※3: value obtained when the value of the standard deviation of Example 1-1 is normalized at 1.
※4: value of the photoelectric conversion efficiency after the test/ the initial photoelectric conversion efficiency.

TABLE 7

| | | |
|---|---|---|
| film-forming conditions | raw material gas | SiH₄: 20 cm³/min(normal) |
| in the vacuum vessel | | H₂: 100 cm³/min(normal) |
| 211 | | PH₃(diluted by H₂ to 2%): |
| | | 50 cm³/min(normal) |
| | substrate | 300° C. |
| | temperature | |
| | gas pressure | 100 Pa |
| film-forming conditions | raw material gas | SiH₄: 200 cm³/min(normal) |
| in the vacuum vessel | | H₂ : 3000 cm³/min(normal) |
| 212 | | |
| | substrate | 300° C. |
| | temperature | |
| | gas pressure | 300 Pa |
| film-forming conditions | raw material gas | SiH₄: 10 cm³/min(normal) |
| in the vacuum vessel | | H₂: 800 cm³/min(normal) |
| 213 | | BF₃(diluted by H₂ to |
| | | 2%): 100 cm³/min(normal) |
| | substrate | 200° C. |
| | temperature | |
| | gas pressure | 150 Pa |

TABLE 8

| | direct current | | average value of | uniformity of | change in the photoelectric |
|---|---|---|---|---|---|
| | potential of the | lattice | photoelectric | photoelectric | conversion efficiency by the high |
| | power application | pattern type | conversion | conversion | temperature-high humidity |
| | electrode ※1 | method ※2 | efficiency ※3 | efficiency ※4 | reverse bias application test ※5 |
| Example 4-1 | −50 V | 1 | 1 | 1 | 0.98 |
| Example 4-2 | −100 V | 1.0 | 1.02 | 1.02 | 0.98 |
| Example 4-3 | −200 V | 1.0 | 1.04 | 1.00 | 0.98 |
| Example 4-4 | −300 V | 1.0 | 1.04 | 1.02 | 0.98 |
| Comparative | −50 V | 1.0 | 0.98 | 1.06 | 0.98 |
| Example 4-1 | | | | | |
| Comparative | −100 V | 0.98 | 0.96 | 1.10 | 0.96 |
| Example 4-2 | | | | | |
| Comparative | −200 V | 0.97 | 0.96 | 1.08 | 0.95 |
| Example 4-3 | | | | | |
| Comparative | −300 V | 0.95 | 0.95 | 1.13 | 0.94 |
| Example -4 | | | | | |

※1: value obtained when the number of the lattices not peeled in Example 1-1 is normalized at 1.
※2: value obtained when the value of the photoelectric conversion efficiency of Example 1-1 is normalized at 1.
※3: value obtained when the value of the standard deviation of Example 1-1 is normalized at 1.
※4: value of the photoelectric conversion efficiency after the test/ the initial photoelectric conversion efficiency.

What is claimed is:

1. A deposited film-forming apparatus by means of high frequency plasma CVD, said apparatus having a power application electrode for forming a deposited film on a substrate positioned in a film-forming vacuum vessel, a high frequency power source connected to said power application electrode, a direct current power source which is connected to said power application electrode and is connected with said high frequency power source in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said power application electrode and said direct current power source such that said arc discharge preventive means is connected with said direct current power source in series connection and is connected with said high frequency power source in parallel connection.

2. The deposited film-forming apparatus according to claim 1, wherein said detector functions to detect a scanty change in discharge current or discharge voltage on the basis when said discharge current or said discharge voltage is in a steady state, as a symptom of occurrence of arc discharge.

3. The deposited film-forming apparatus according to claim 1, wherein said arc discharge preventive means is a means to cut off an electrical connection between said direct current power source and said power application electrode.

4. The deposited film-forming apparatus according to claim 1, wherein said arc discharge preventive means is a means to switch a circuit involving said direct current power source and said power application electrode so as to apply a reverse potential to said power application electrode with respect to its potential.

5. The deposited film-forming apparatus according to claim 1, wherein when said deposited film is formed on said substrate, the substrate has a potential which is higher than that of said power application electrode.

6. The deposited film-forming apparatus according to claim 1, wherein the distance between said power application electrode and said substrate is in a range of 3 mm to 30 mm.

7. The deposited film-forming apparatus according to claim 1, wherein said deposited film formed on said substrate is a silicon series deposited film.

8. A deposited film-forming apparatus by means of high frequency plasma CVD, said apparatus having a plurality of power application electrodes each for forming a deposited film on a substrate positioned in a film-forming vacuum vessel, a plurality of high frequency power sources each being connected to one of said plurality of power application electrodes, a direct current power source which is connected to said plurality of power application electrodes through a brunch point of an electric circuit involving said plurality of power application electrodes and is connected with said plurality of high frequency power sources in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said brunch point and said direct current power source such that said arc discharge preventive means is connected with said direct current power source in series connection and is connected with said plurality of high frequency power sources in parallel connection.

9. The deposited film-forming apparatus according to claim 8, wherein said detector functions to detect a scanty change in discharge current or discharge voltage on the basis when said discharge current or said discharge voltage is in a steady state, as a symptom of occurrence of arc discharge.

10. The deposited film-forming apparatus according to claim 8, wherein said arc discharge preventive means is a means to cut off an electrical connection between said direct current power source and said plurality of power application electrodes.

11. The deposited film-forming apparatus according to claim 8, wherein said arc discharge preventive means is a means to switch a circuit involving said direct current power source and said plurality of power application electrodes so as to apply a reverse potential to said plurality of power application electrodes with respect to their potential.

12. The deposited film-forming apparatus according to claim 8, wherein when said deposited film is formed on said substrate, the substrate has a potential which is higher than that of any of said plurality of power application electrodes.

13. The deposited film-forming apparatus according to claim 8, wherein the distance between said substrate and each of said plurality of power application electrodes is in a range of 3 mm to 30 mm.

14. The deposited film-forming apparatus according to claim 8, wherein said deposited film formed on said substrate is a silicon series deposited film.

15. A deposited film-forming process by using a deposited film-forming apparatus by means of high frequency plasma CVD and having a power application electrode for forming a deposited film on a substrate positioned in a film-forming vacuum vessel, a high frequency power source connected to said power application electrode, a direct current power source which is connected to said power application electrode and is connected with said high frequency power source in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said power application electrode and said direct current power source such that said arc discharge preventive means is connected with said direct current power source in series connection and is connected with said high frequency power source in parallel connection, characterized in that when a symptom of occurrence of arc discharge is detected by said detector, said arc discharge preventive means is actuated.

16. The deposited film-forming process according to claim 15, wherein said detector functions to detect a scanty change in discharge current or discharge voltage on the basis when said discharge current or said discharge voltage is in a steady state, as said symptom of occurrence of arc discharge.

17. The deposited film-forming process according to claim 15, wherein said arc discharge preventive means is a means to cut off an electrical connection between said direct current power source and said power application electrode.

18. The deposited film-forming process according to claim 15, wherein said arc discharge preventive means is a means to switch a circuit involving said direct current power source and said power application electrode so as to apply a reverse potential to said power application electrode with respect to its potential.

19. The deposited film-forming process according to claim 15, wherein when said deposited film is formed on said substrate, the substrate has a potential which is higher than that of said power application electrode.

20. The deposited film-forming process according to claim 15, wherein the distance between said substrate and said power application electrode is in a range of 3 mm to 30 mm.

21. The deposited film-forming process according to claim 15, wherein said deposited film is formed at a pressure in a range of 100 to 5000 Pa.

22. The deposited film-forming process according to claim 15, wherein said deposited film is formed with a residence time of raw material gas, which falls in a range of 0.01 to 10 seconds.

23. The deposited film-forming process according to claim 15, wherein said deposited film is formed with a high frequency power density in a range of 0.01 to 12 W/cm³.

24. The deposited film-forming process according to claim 15, wherein said deposited film formed is a silicon series deposited film.

25. The deposited film-forming process according to claim 15, wherein raw material gas is introduced into said apparatus and simultaneously with this, a prescribed high frequency power from said high frequency power source and a prescribed direct current voltage from said direct current power source are supplied to said power application electrode to generate a plasma, whereby said raw material gas is decomposed to cause the formation of a deposited film on a substrate positioned in said apparatus.

26. A deposited film-forming process by using a deposited film-forming apparatus by means of plasma CVD and having a plurality of power application electrodes each for forming a deposited film on a substrate positioned in a film-forming vacuum vessel, a plurality of high frequency power sources each being connected to one of said plurality of power application electrodes, a direct current power source which is connected to said plurality of power application electrodes through a brunch point of an electric circuit involving said plurality of power application electrodes and is connected with said plurality of high frequency power sources in parallel connection, a detector for detecting a symptom of occurrence of arc discharge, and an arc discharge preventive means for preventing occurrence of arc discharge based on said symptom of occurrence of arc discharge which is detected by said detector, wherein said arc discharge preventive means is connected between said brunch point and said direct current power source such that said arc discharge preventive means is connected with said direct current power source in series connection and is connected with said plurality of high frequency power sources in parallel connection, characterized in that when a symptom of occurrence of arc discharge which is detected by said detector, said arc discharge preventive means is actuated.

27. The deposited film-forming process according to claim 26, wherein said detector functions to detect a scanty change in discharge current or discharge voltage on the basis when said discharge current or said discharge voltage is in a steady state, as said symptom of occurrence of arc discharge.

28. The deposited film-forming process according to claim 26, wherein said arc discharge preventive means is a means to cut off an electrical connection between said direct current power source and said plurality of power application electrodes.

29. The deposited film-forming process according to claim 26, wherein said arc discharge preventive means is a means to switch a circuit involving said direct current power source and said plurality of power application electrodes so as to apply a reverse potential to said plurality of power application electrodes with respect to their potential.

30. The deposited film-forming process according to claim 26, wherein when said deposited film is formed on said substrate, the substrate has a potential which is higher than that of any of said plurality of power application electrodes.

31. The deposited film-forming process according to claim 26, wherein the distance between said substrate and each of said plurality of power application electrodes is in a range of 3 mm to 30 mm.

32. The deposited film-forming process according to claim 26, wherein said deposited film is formed at a pressure in a range of 100 to 5000 Pa.

33. The deposited film-forming process according to claim 26, wherein said deposited film is formed with a residence time of raw material gas, which falls in a range of 0.01 to 10 seconds.

34. The deposited film-forming process according to claim 26, wherein said deposited film is formed with a high frequency power density in a range of 0.01 to 12 W/cm³.

35. The deposited film-forming process according to claim 26, wherein said deposited film formed is a silicon series deposited film.

36. The deposited film-forming process according to claim 26, wherein raw material gas is introduced into said apparatus and simultaneously with this, a prescribed high frequency power from said high frequency power source and a prescribed direct current voltage from said direct current power source are supplied to said power application electrode to generate a plasma, whereby said raw material gas is decomposed to cause the formation of a deposited film on a substrate positioned in said apparatus.
